(19) United States
(12) Patent Application Publication
(10) Pub. No.: US 2023/0422569 A1
(43) Pub. Date: Dec. 28, 2023

(54) DISPLAY DEVICE

(71) Applicant: Samsung Display Co., Ltd., Yongin-si (KR)

(72) Inventors: Sunkyu Joo, Yongin-si (KR); Jaecheol Park, Yongin-si (KR); Keunchan Oh, Yongin-si (KR); Yeogeon Yoon, Yongin-si (KR)

(73) Assignee: Samsung Display Co., Ltd., Yongin-si (KR)

(21) Appl. No.: 18/191,391

(22) Filed: Mar. 28, 2023

(30) Foreign Application Priority Data
Jun. 28, 2022 (KR) 10-2022-0079273

(51) Int. Cl. H10K 59/35; H10K 59/80

(52) U.S. Cl. CPC H10K 59/35; H10K 59/12; H10K 59/875

(57) ABSTRACT

A display apparatus includes first sub-pixels, second sub-pixels, and third sub-pixels, an organic light-emitting diode including at least two emission layers emitting light of different colors, a color conversion layer disposed over the first sub-pixels and including quantum dots converting incident light into light of a first color, a first color filter disposed over the color conversion layer, a first transmission layer disposed over the second sub-pixels, a second color filter disposed over the first transmission layer, a second transmission layer disposed over the third sub-pixels, and a third color filter disposed over the second transmission layer, wherein a material of the first transmission layer is a same material as the second transmission layer.

### CROSS REFERENCE TO RELATED APPLICATION(S)

This application claims priority to and benefits of Korean Patent Application No. 10-2022-0079273 under 35 U.S.C. § 119, filed on Jun. 28, 2022, in the Korean Intellectual Property Office (KIPO), the entire contents of which are incorporated herein by reference.

### BACKGROUND

### 1. Technical Field

The disclosure relates to a structure of a display apparatus or display device.

### 2. Description of the Related Art

Display apparatuses visually display data. Such display apparatuses include a substrate divided into a display area and a peripheral area. In the display area, scan lines and data lines are arranged to be insulated from each other, and sub-pixels may be included. Also, in the display area, a thin-film transistor and a sub-pixel electrode electrically connected to the thin-film transistor may be provided to be in correspondence with each of the sub-pixels. Also, the display area may also include an opposite electrode commonly provided in the sub-pixels. The peripheral area may include various wires for transferring electrical signals to the display area, a scan driver, a data driver, a controller, a pad unit, etc.

Applications of such display apparatuses have diversified. Accordingly, various designs for improving the quality of display apparatuses have been attempted.

### SUMMARY

One or more embodiments include a display apparatus in which a color (or light of color) emitted from each sub-pixel is clearly implemented while light extraction efficiency is increased and manufacturing cost is reduced. However, the embodiments are only examples, and the scope of the disclosure is not limited thereto.

Additional aspects will be set forth in part in the description which follows and, in part, will be apparent from the description, or may be learned by practice of the embodiments of the disclosure.

According to one or more embodiments, a display apparatus may include first sub-pixels of a first color, second sub-pixels of a second color, and third sub-pixels of a third color which are apart from each other with a non-pixel area disposed between the first sub-pixels, the second sub-pixels, and the third sub-pixels, a plurality of organic light-emitting diodes disposed over a lower substrate to correspond to the first sub-pixels, the second sub-pixels, and the third sub-pixels, respectively, and each including a first electrode, at least two emission layers emitting light of different colors, and a second electrode, a color conversion layer disposed over one of the organic light-emitting diodes corresponding to one of the first sub-pixels, and including quantum dots converting incident light into light of the first color, a first color filter disposed over the color conversion layer and transmitting light of the first color, a first transmission layer disposed over one of the organic light-emitting diodes corresponding to one of the second sub-pixels, a second color filter disposed over the first transmission layer and transmitting light of the second color different from the first color, a second transmission layer disposed over one of the organic light-emitting diodes corresponding to one of the third sub-pixels, and a third color filter disposed over the second transmission layer and transmitting light of the third color different from the first color and the second color, wherein a material of the first transmission layer is identical to a material of the second transmission layer.

In an embodiment, the first transmission layer and the second transmission layer may extend toward the non-pixel area, and in the non-pixel area, an end portion of the first transmission layer and an end portion of the second transmission layer may overlap an end portion of the color conversion layer in a plan view.

In an embodiment, a column spacer may be arranged between two adjacent third sub-pixels among the third sub-pixels.

In an embodiment, the display apparatus may further include a material layer arranged between the two adjacent third sub-pixels, the material layer and the color conversion layer including a same material, wherein a portion of the first color filter, a portion of the second color filter, and a portion of the third color filter may each extend between the two adjacent third sub-pixels and may overlap each other in a plan view, and the portion of the first color filter, the portion of the second color filter, and the portion of the third color filter, and the material layer may overlap the column spacer in a plan view.

In an embodiment, the column spacer, the first transmission layer, and the second transmission layer may include a same material.

In an embodiment, the organic light-emitting diodes may emit blue light and green light, and the quantum dots may convert incident light into red light.

In an embodiment, the organic light-emitting diodes may emit blue light and red light, and the quantum dots may convert the incident light into green light.

In an embodiment, the organic light-emitting diodes may emit red light, green light, and blue light.

In an embodiment, the display apparatus may further include fourth sub-pixels of a fourth color, and a third transmission layer overlapping one of the organic light-emitting diodes corresponding to one of the fourth sub-pixels in a plan view.

In an embodiment, a material of the third transmission layer may be identical to a material of the first transmission layer and a material of the second transmission layer.

In an embodiment, the fourth sub-pixels and the third sub-pixels may be arranged along a same row, and one of the fourth sub-pixels may be arranged between two adjacent third sub-pixels among the third sub-pixels.

In an embodiment, the display apparatus may further include a capping layer, wherein a first portion of the capping layer may be disposed on a lower surface of the color conversion layer, a second portion of the capping layer may be disposed on an upper surface of the first transmission layer, and a third portion of the capping layer may be disposed on an upper surface of the second transmission layer.

In an embodiment, the capping layer may include a light-transmissive inorganic material.

According to one or more embodiments, a display apparatus may include first sub-pixels of a first color, second sub-pixels of a second color, and third sub-pixels of a third color which are apart from each other with a non-pixel area disposed between the first sub-pixels, the second sub-pixels, and the third sub-pixels, organic light-emitting diodes disposed over a lower substrate to correspond to the first sub-pixels, the second sub-pixels, and the third sub-pixels, and including a first electrode, at least two emission layers emitting light of different colors, and a second electrode, a color conversion layer disposed over one of the organic light-emitting diodes corresponding to one of the first sub-pixels, and including quantum dots converting incident light into light of the first color, a first color filter disposed over the color conversion layer and transmitting light of the first color, a first transmission layer disposed over one of the organic light-emitting didoes corresponding to one of the second sub-pixels, a second color filter disposed over the first transmission layer and transmitting light of the second color different from the first color, a second transmission layer disposed over one of the organic light-emitting diodes corresponding to one of the third sub-pixels, and a third color filter disposed over the second transmission layer and transmitting light of the third color different from the first color and the second color, wherein the first color filter, the second color filter, and the third color filter may extend toward the non-pixel area, and at least one end portion of the first transmission layer or the second transmission layer may overlap a portion of the color conversion layer, a portion of the first color filter, a portion of the second color filter, and a portion of the third color filter, in the non-pixel area in a plan view.

In an embodiment, a column spacer may be arranged between two third sub-pixels adjacent to each other.

In an embodiment, the display apparatus may further include a first color filter layer, the first color filter layer and the first color filter including a same material, a second color filter layer, the second color filter layer and the second color filter including a same material, a third color filter layer, the third color filter layer and the third color filter including a same material, and a material layer, the material layer and the color conversion layer including a same material, wherein the first color filter layer, the second color filter layer, the third color filter layer, and the material layer may be arranged between the two adjacent third sub-pixels, and the first color filter layer, the second color filter layer, the third color filter layer, and the material layer may overlap the column spacer in a plan view.

In an embodiment, the column spacer, the first transmission layer, and the second transmission layer may include a same material.

In an embodiment, the organic light-emitting diodes may emit red light, green light, and blue light.

In an embodiment, the display apparatus may further include fourth sub-pixels of a fourth color, and a third transmission layer overlapping one of the organic light-emitting diodes corresponding to one of the fourth sub-pixels in a plan view.

In an embodiment, a material of the third transmission layer may be identical to a material of the first transmission layer and a material of the second transmission layer.

In an embodiment, the fourth sub-pixels and the third sub-pixels may be arranged along a same row, and one of the fourth sub-pixels may be arranged between two adjacent third sub-pixels among the third sub-pixels.

In an embodiment, the display apparatus may further include a capping layer, wherein a first portion of the capping layer may be disposed on a lower surface of the color conversion layer, a second portion of the capping layer may be disposed on an upper surface of the first transmission layer, and a third portion of the capping layer may be disposed on an upper surface of the second transmission layer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a display apparatus according to an embodiment;

FIG. 2 is a schematic cross-sectional view of a display apparatus of FIG. 1 taken along line A-A′ of FIG. 1;

FIG. 3 is a schematic plan view of a portion of a display area of a display apparatus according to an embodiment;

FIG. 4A is a schematic cross-sectional view of a color panel of FIG. 3 taken along line I-I′ of FIG. 3;

FIG. 4B is a schematic cross-sectional view of the color panel of FIG. 3 taken along line II-IT of FIG. 3;

FIG. 5 is a schematic plan view of a portion of a display area of a display apparatus according to another embodiment;

FIG. 6A is a schematic cross-sectional view of a color panel of FIG. 5 taken along line III-III′ of FIG. 5;

FIG. 6B is a schematic cross-sectional view of the color panel of FIG. 5 taken along line IV-IV′ of FIG. 5;

FIG. 7 is a schematic plan view of a portion of a display area of a display apparatus according to another embodiment;

FIG. 8A is a schematic cross-sectional view of a color panel of FIG. 7 taken along line V-V′ of FIG. 7; and

FIG. 8B is a schematic cross-sectional view of the color panel of FIG. 7 taken along line VI-VI′ of FIG. 7.

### DETAILED DESCRIPTION OF THE EMBODIMENTS

Reference will now be made in detail to embodiments, examples of which are illustrated in the accompanying drawings, wherein like reference numerals refer to like elements throughout the specification. In this regard, the embodiments may have different forms and should not be construed as being limited to the descriptions set forth herein. Accordingly, the embodiments are merely described below, by referring to the figures, to explain aspects of the description.

Various modifications may be applied to the embodiments, and particular embodiments will be illustrated in the drawings and described in the detailed description section. The effect and features of the embodiments, and a method to achieve the same, will be clearer referring to the detailed descriptions below with the drawings. However, the embodiments may be implemented in various forms, not by being limited to the embodiments presented below.

Hereinafter, embodiments will be described, in detail, with reference to the accompanying drawings, and in the description with reference to the drawings, the same or corresponding components are indicated by the same reference numerals and redundant descriptions thereof are omitted.

In the following embodiment, it will be understood that although the terms “first,” “second,” and the like may be used herein to describe various components, these components should not be limited by these terms. These terms are only used to distinguish one component from another.

The term “and/or” includes all combinations of one or more of which associated configurations may define. For example, “A and/or B” may be understood to mean “A, B, or A and B.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the example term “below” can encompass both an orientation of above and below. Furthermore, the apparatus may be otherwise oriented (e.g., rotated 90 degrees or at other orientations), and, as such, the spatially relative descriptors used herein interpreted accordingly.

In the following embodiment, the expression of singularity in the specification includes the expression of plurality unless clearly specified otherwise in context.

In the following embodiment, it will be further understood that the terms “comprises” and/or “comprising” used herein specify the presence of stated features or components, but do not preclude the presence or addition of one or more other features or components.

In the following embodiment, it will be understood that in case that a layer, region, or component is referred to as being “formed on” another layer, region, or component, it can be directly or indirectly formed on the other layer, region, or component. For example, intervening layers, regions, or components may be present.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Sizes of components in the drawings may be exaggerated for convenience of explanation. In other words, since sizes and thicknesses of components in the drawings are arbitrarily illustrated for convenience of explanation, the following embodiments are not limited thereto.

When a certain embodiment may be implemented differently, a specific process order may be performed differently from the described order. For example, two consecutively described processes may be performed substantially at a same time or performed in an order opposite to the described order.

It will be understood that when a layer, region, or component is referred to as being “connected to” another layer, area, or component, it can be directly or indirectly connected to the other layer, region, or component. For example, intervening layers, regions, or components may be present. For example, in the specification, when a layer, region, or component is electrically connected to another layer, region, or component, the layers, regions, or components may not only be directly electrically connected, but may also be indirectly electrically connected via another layer, region, or component therebetween.

The term “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

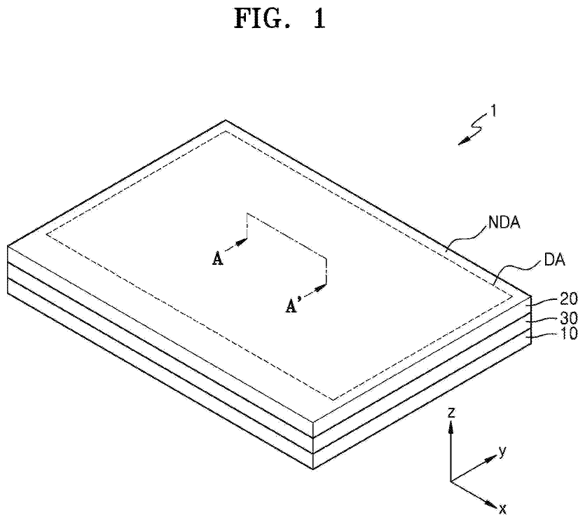

FIG. 1 is a schematic perspective view of a display apparatus according to an embodiment.

Referring to FIG. 1, a display apparatus 1 may display an image. The display apparatus 1 may provide an image via sub-pixels arranged in a display area DA. Each of the sub-pixels of the display apparatus 1 may be an area in which light of a certain color may be emitted. The display apparatus 1 may display an image by using light emitted from the sub-pixels. For example, the sub-pixel may emit light of a red color, a green color, or a blue color. As another example, the sub-pixel may emit light of a red color, a green color, a blue color, or a white color.

A non-display area NDA may at least partially surround the display area DA. In an embodiment, the non-display area NDA may completely surround the display area DA. The non-display area NDA may be where an image is not provided.

The display area DA may have a polygonal shape including a quadrangle as shown in FIG. 1. For example, the display area DA may have a rectangular shape in which a horizontal length is greater than a vertical length, or a rectangular shape in which a horizontal length is less than a vertical length, or may have a square shape. As another example, the display area DA may have various shapes such as an ellipse or a circle. In an embodiment, the display apparatus 1 may include a light-emitting panel 10, a color panel 20, and a filling layer 30. The light-emitting panel 10, the filling layer 30, and the color panel 20 may be stacked each other in a thickness direction (for example, a z direction).

The display apparatus 1 having the above-described structure may be included in a mobile phone, a television, a billboard, a monitor, a tablet personal computer (PC), a laptop, or the like.

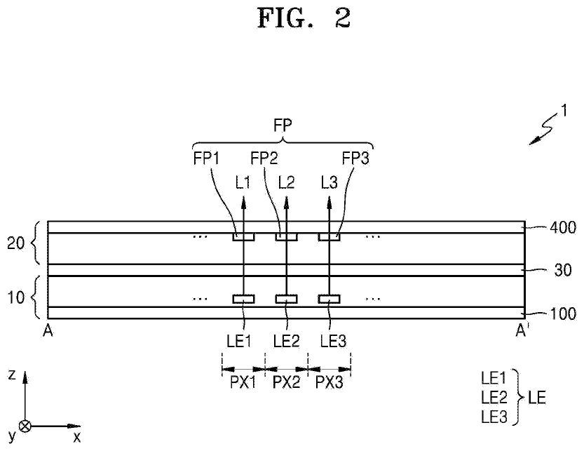

FIG. 2 is a schematic cross-sectional view of a display apparatus 1 of FIG. 1 taken along line A-A′ of FIG. 1.

Referring to FIG. 2, the display apparatus 1 may include a first sub-pixel PX1, a second sub-pixel PX2, and a third sub-pixel PX3. Each of the first sub-pixel PX1, the second sub-pixel PX2, and the third sub-pixel PX3 may be subpixels emitting light of different colors. For example, the first sub-pixel PX1 may emit first color light L1, the second sub-pixel PX2 may emit second color light L2, and the third sub-pixel PX3 may emit third color light L3. For example, the first color light L1 may be red light, the second color light L2 may be blue light, and the third color light L3 may be green light.

The display apparatus 1 may include the light-emitting panel 10, the color panel 20, and the filling layer 30. The light-emitting panel 10 may include a lower substrate 100 and a light-emitting element LE. The light-emitting element LE may be, for example, an organic light-emitting diode. In an embodiment, each of the first sub-pixel PX1, the second sub-pixel PX2, and the third sub-pixel PX3 may include the light-emitting element LE. For example, the first sub-pixel PX1 may include a first light-emitting element LE1. The first light-emitting element LE1 may be a first organic light-emitting diode. The second sub-pixel PX2 may include a second light-emitting element LE2. The second light-emitting element LE2 may be a second organic light-emitting diode. The third sub-pixel PX3 may include a third light-emitting element LE3. The third light-emitting element LE3 may be a third organic light-emitting diode.

The first light-emitting element LE1, the second light-emitting element LE2, and the third light-emitting element LE3 may emit light of a same color. In an embodiment, each of the first light-emitting element LE1, the second light-emitting element LE2, and the third light-emitting element LE3 may emit mixed-color light in which blue light and green light are mixed. In an embodiment, each of the first light-emitting element LE1, the second light-emitting element LE2, and the third light-emitting element LE3 may emit mixed-color light in which blue light and red light are mixed. In an embodiment, each of the first light-emitting element LE1, the second light-emitting element LE2, and the third light-emitting element LE3 may emit mixed-color light in which blue light, green light, and the red light are mixed.

Each of the first light-emitting element LE1, the second light-emitting element LE2, and the third light-emitting element LE3 may include a structure in which two or more emitting units emitting light of different colors are sequentially stacked each other. For example, each of the first organic light-emitting diode, the second organic light-emitting diode, and the third organic light-emitting diode may be a tandem light-emitting element. Each of the first organic light-emitting diode, the second organic light-emitting diode, and the third organic light-emitting diode may have a structure of a stack of emitting units, thereby improving color purity and emission efficiency. In an embodiment, each of the first light-emitting element LE1, the second light-emitting element LE2, and the third light-emitting element LE3 may include a structure of a stack of emitting units emitting blue light and green light. In an embodiment, each of the first light-emitting element LE1, the second light-emitting element LE2, and the third light-emitting element LE3 may include a structure of a stack of emitting units emitting blue light and red light. In an embodiment, each of the first light-emitting element LE1, the second light-emitting element LE2, and the third light-emitting element LE3 may include a structure of a stack of emitting units emitting red light, blue light, and green light.

The color panel 20 may include an upper substrate 400 and a filter portion FP. In an embodiment, the filter portion FP may include a first filter portion FP1, a second filter portion FP2, and a third filter portion FP3. Light emitted from the first light-emitting element LE1 may be emitted as the first color light L1 through the first filter portion FP1. Light emitted from the second light-emitting element LE2 may be emitted as the second color light L2 through the second filter portion FP2. Light emitted from the third light-emitting element LE3 may be emitted as the third color light L3 through the third filter portion FP3.

The filter portion FP may include a functional layer and a color filter layer. In an embodiment, the functional layer may include a first quantum dot layer, a first transmission layer, and a second transmission layer. In an embodiment, the color filter layer may include a first color filter, a second color filter, and a third color filter. In an embodiment, the first filter portion FP1 may include the first quantum dot layer and the first color filter, the second filter portion FP2 may include the first transmission layer and the second color filter, and the third filter portion FP3 may include the second transmission layer and the third color filter. As another example, in an embodiment, the third filter portion FP3 may include the first quantum dot layer and the third color filter, the second filter portion FP2 may include the first transmission layer and the second color filter, and the first filter portion FP1 may include the second transmission layer and the first color filter.

The filter portion FP may be disposed (e.g., directly disposed) on the upper substrate 400 (for example, on a lower surface of the upper substrate 400). In this regard, an expression “directly disposed on the upper substrate” may be to mean that the first color filter, the second color filter, and the third color filter are formed (e.g., directly formed) on the upper substrate 400 to manufacture the color panel 20. Afterwards, the color panel 20 may be bonded to the light-emitting panel 10 so that the first filter portion FP1, the second filter portion FP2, and the third filter portion FP3 face the first light-emitting element LE1, the second light-emitting element LE2, and the third light-emitting element LE3, respectively.

The filling layer 30 may be disposed between the light-emitting panel 10 and the color panel 20. The filling layer 30 may bond the light-emitting panel 10 and the color panel 20 together. In an embodiment, the filling layer 30 may include a thermosetting or photocurable filler. Although not shown, any one of the light-emitting panel 10 and the color panel 20 may include a column spacer. For example, the light-emitting panel 10 may include a column spacer protruding toward the color panel 20 (e.g., in the z direction). As another example, the color panel 20 may include a column spacer protruding toward the light-emitting panel 10 (e.g., in the z direction). Therefore, light-emitting elements LE and filter portions FP may each maintain a certain distance, and the display apparatus 1 may maintain uniform luminance according to positions.

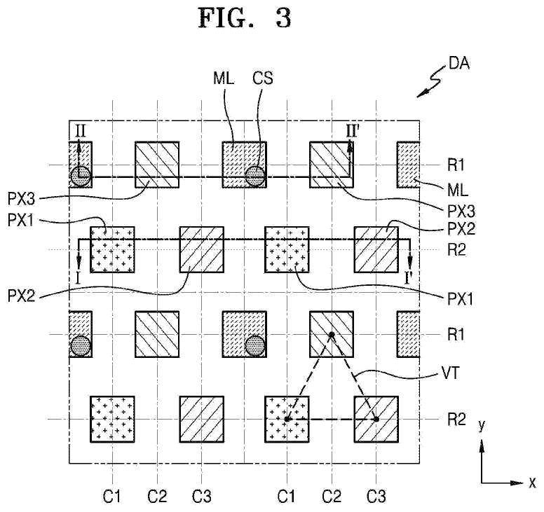

FIG. 3 is a schematic plan view of a portion of a display area of a display apparatus 1 according to an embodiment.

Referring to FIG. 3, the display apparatus 1 may include an array of sub-pixels arranged in the display area DA. The array of the sub-pixels may include first sub-pixels PX1, second sub-pixels PX2, and third sub-pixels PX3 that are two-dimensionally arranged. In some embodiments, the array of the sub-pixels may have a configuration in which a minimal repeating unit (or minimal repeating part) including one first sub-pixel PX1, one second sub-pixel PX2, and one third sub-pixel PX3 is repeatedly arranged in an x direction and a y direction. The minimal repeating unit may be a repeating unit having the smallest number of sub-pixels. Centers of the first sub-pixel PX1, the second sub-pixel PX2, and the third sub-pixel PX3 included in the minimal repeating unit may be located at vertices of a virtual triangle VT. In some embodiments, the virtual triangle VT may be an acute triangle, for example, an equilateral triangle.

The array of the sub-pixels may have a two-dimensional configuration of the minimal repeating units, and may have different arrangements in the x direction and the y direction.

In case that viewing the arrangement of the sub-pixels in the x direction, the array of the sub-pixels may have a configuration in which two rows in the x direction are repeatedly arranged. The third sub-pixels PX3 may be arranged along a first row R1 in the x direction, and the first sub-pixel PX1 and the second sub-pixel PX2 may be alternately arranged along a second row R2 in the x direction, the second row R2 being parallel to the first row R1. The array of the sub-pixels may have a structure in which the first row R1 and the second row R2 of the above-described structure are repeatedly arranged.

When viewing the arrangement of the sub-pixels in the y direction, sub-pixels emitting light of a same color may be arranged in each column in the y direction. The first sub-pixels PX1 may be arranged along a first column C1, and the third sub-pixels PX3 may be arranged along a second column C2, and the second sub-pixels PX2 may be arranged along a third column C3. The array of the sub-pixels may have a structure in which the first column C1, the second column C2, and the third column C3 are repeatedly arranged.

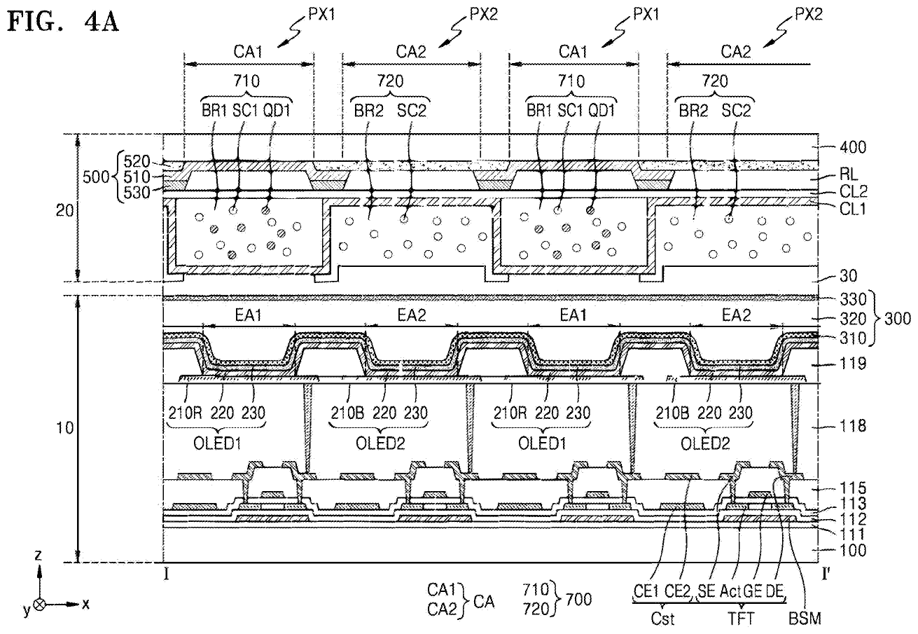

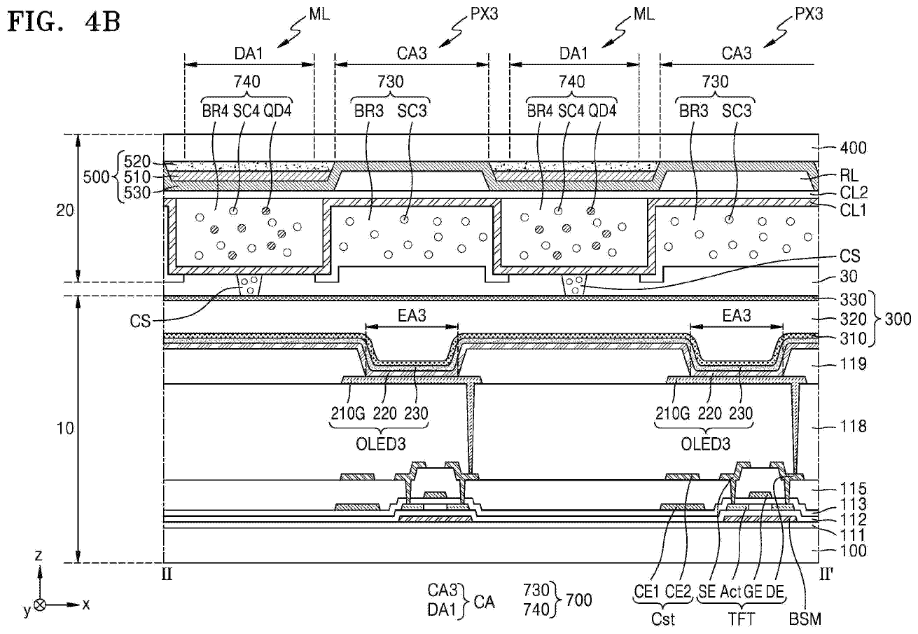

The first sub-pixels PX1 emitting a first color, the second sub-pixels PX2 emitting a second color, and the third sub-pixels PX3 emitting a third color may be arranged apart from each other with a non-pixel area therebetween. As the first sub-pixels PX1 and the second sub-pixels PX2 are alternately arranged with the third sub-pixels PX3 therebetween in the x direction, a distance between two adjacent third sub-pixels PX3 is greater than a distance between the first and second sub-pixels PX1 and PX2 adjacent to each other. Accordingly, a material layer area ML may be arranged between the two adjacent third sub-pixels PX3 (e.g., in the x direction). For example, the third sub-pixel PX3 and the material layer area ML may be alternately arranged along the first row R1 in the x direction. The material layer area ML is described in detail with reference to FIGS. 4A and 4B.

FIG. 4A is a schematic cross-sectional view of a color panel of FIG. 3 taken along line I-I′ of FIG. 3, and FIG. 4B is a schematic cross-sectional view of the color panel of FIG. 3 taken along line II-IT of FIG. 3.

Referring to FIGS. 4A and 4B, the display apparatus 1 may include the first sub-pixel PX1, the second sub-pixel PX2, the third sub-pixel PX3, and the material layer area ML, which are arranged in the display area DA. The first sub-pixel PX1, the second sub-pixel PX2, and the third sub-pixel PX3 may implement light of different colors. For example, the first sub-pixel PX1 may implement red light, the second sub-pixel PX2 may implement blue light, and the third sub-pixel PX3 may implement green light. The material layer area ML may be where light for implementing an image is not emitted, and may correspond to a kind of dummy sub-pixel.

The display apparatus 1 may include the light-emitting panel 10, the color panel 20, and the filling layer 30. The light-emitting panel 10 may include the lower substrate 100, and a light-emitting element disposed over the lower substrate 100 and including an emission layer 220. The light-emitting element may be an organic light-emitting diode. In an embodiment, the light-emitting panel 10 may include a first organic light-emitting diode OLED1, a second organic light-emitting diode OLED2, and a third organic light-emitting diode OLED3, which are disposed over the lower substrate 100. The first organic light-emitting diode OLED1, the second organic light-emitting diode OLED2, and the third organic light-emitting diode OLED3 may include the emission layer 220.

Hereinafter, a stack structure of the light-emitting panel 10 is described in detail. In an embodiment, the light-emitting panel 10 may include the lower substrate 100, a first buffer layer 111, a bias electrode BSM, a second buffer layer 112, a thin-film transistor TFT, a storage capacitor Cst, a gate insulating layer 113, an insulating interlayer 115, a planarization layer 118, a light-emitting element, and an encapsulation layer 300. The thin-film transistor TFT may include a semiconductor layer Act, a gate electrode GE, a source electrode SE, and a drain electrode DE. The storage capacitor Cst may include a first electrode CE1 and a second electrode CE2.

The lower substrate 100 may include a glass material, a ceramic material, a metal material, or a flexible or bendable material. In case that the lower substrate 100 is flexible or bendable, the lower substrate 100 may include polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate. However, embodiments are not limited thereto. The lower substrate 100 may have a single-layered or multilayer structure of the material, and may further include an inorganic layer when having the multilayer structure. In an embodiment, the lower substrate 100 may have a structure of an organic material/inorganic material/organic material.

A barrier layer (not shown) may be further included between the lower substrate 100 and the first buffer layer 111. The barrier layer may prevent or minimize impurities from penetrating into the semiconductor layer Act from the lower substrate 100. The barrier layer may include an inorganic material such as an oxide, a nitride, the like, or a combination thereof, an organic material, or an organic/inorganic composite, and may have a single-layered or multilayer structure of the inorganic material and the organic material.

The bias electrode BSM may be disposed on the first buffer layer 111 to correspond to the thin-film transistor TFT. In an embodiment, a voltage may be applied to the bias electrode BSM. Also, the bias electrode BSM may prevent external light from reaching the semiconductor layer Act. Accordingly, characteristics of the thin-film transistor TFT may be stabilized. The bias electrode BSM may be omitted in some embodiments.

The semiconductor layer Act may be disposed on the second buffer layer 112. The semiconductor layer Act may include amorphous silicon or polysilicon. In another embodiment, the semiconductor layer Act may include an oxide of at least one material selected from the group including Indium (In), gallium (Ga), tin (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). In some embodiments, the semiconductor layer Act may include a Zn oxide, an In—Zn oxide, a Ga—In—Zn oxide, the like, or a combination thereof as a Zn-oxide-based material. In another embodiment, the semiconductor layer Act may be an In—Ga—Zn—O (IGZO), In—Sn—Zn—O (ITZO), or In—Ga—Sn—Zn—O (IGTZO) semiconductor containing a metal such as In, Ga, Sn, the like, or a combination thereof in a zinc oxide (ZnO). The semiconductor layer Act may include a channel region, and a source region and a drain region respectively at sides (e.g., both sides) of the channel region. The semiconductor layer Act may be formed as a single layer or a multilayer.

The gate electrode GE may be disposed over the semiconductor layer Act with the gate insulating layer 113 therebetween. The gate electrode GE may at least partially overlap the semiconductor layer Act. The gate electrode GE may include at least one of molybdenum (Mo), Al, copper (Cu), and Ti, and may be provided as a single layer or a multilayer. For example, the gate electrode GE may be a single layer of Mo. However, embodiments are not limited thereto. The first electrode CE1 of the storage capacitor Cst and the gate electrode GE may be disposed on a same layer. The first electrode CE1 and the gate electrode GE may include a same material.

FIGS. 4A and 4B illustrate that the gate electrode GE of the thin-film transistor TFT and the first electrode CE1 of the storage capacitor Cst are arranged to be apart from each other, but the storage capacitor Cst may overlap the thin-film transistor TFT. The gate electrode GE of the thin-film transistor TFT may function as the first electrode CE1 of the storage capacitor Cst.

The insulating interlayer 115 may be provided to cover (or overlap) the gate electrode GE and the first electrode CE1 of the storage capacitor Cst. For example, the insulating interlayer 115 may include at least one of a silicon oxide (SiOₓ), a silicon nitride (SiNₓ), a silicon oxynitride (SiON), an aluminum oxide (Al₂O₃), a titanium oxide (TiO₂), a tantalum oxide (Ta₂O₅), a hafnium oxide (HfO₂), and a zinc oxide (ZnOₓ). ZnOₓ may include ZnO and/or a zinc peroxide (ZnO₂). However, embodiments are not limited thereto.

The second electrode CE2 of the storage capacitor Cst, the source electrode SE, and the drain electrode DE may be disposed on the insulating interlayer 115. The second electrode CE2 of the storage capacitor Cst, the source electrode SE, and the drain electrode DE may include a conductive material, e.g., including at least one of Mo, Al, Cu, and Ti, and may be provided as a single layer or multilayer including the above-described material. For example, the second electrode CE2, the source electrode SE, and the drain electrode DE may be provided as a multilayer structure of Ti/Al/Ti. The source electrode SE and the drain electrode DE may be connected to the source region or drain region of the semiconductor layer Act via a contact hole.

The second electrode CE2 of the storage capacitor Cst may overlap the first electrode CE1 with the insulating interlayer 115 therebetween, and may constitute the storage capacitor Cst. The insulating interlayer 115 may function as a dielectric layer of the storage capacitor Cst.

The planarization layer 118 may be disposed on the second electrode CE2 of the storage capacitor Cst, the source electrode SE, and the drain electrode DE. The planarization layer 118 may be formed as a single layer or multilayer including an organic material, and may provide a flat upper surface. The planarization layer 118 may include a general-purpose polymer such as benzocyclobutene (BCB), polyimide, hexamethyldisiloxane (HMDSO), polymethylmethacrylate (PMMA), or polystyrene (PS), a polymer derivative having a phenol-based group, an acrylic polymer, an imide-based polymer, an aryl ether-based polymer, an amide-based polymer, a fluorine-based polymer, a p-xylene-based polymer, a vinyl alcohol-based polymer, and a blend thereof. However, embodiments are not limited thereto.

The light-emitting element may be disposed on the planarization layer 118. The light-emitting element may include a sub-pixel electrode (or a first electrode), the emission layer 220, and an opposite electrode 230 (or a second electrode). In an embodiment, the first organic light-emitting diode OLED1, the second organic light-emitting diode OLED2, and the third organic light-emitting diode OLED3 may be disposed on the planarization layer 118. The first organic light-emitting diode OLED1, the second organic light-emitting diode OLED2, and the third organic light-emitting diode OLED3 may include a first sub-pixel electrode 210R, a second sub-pixel electrode 210B, and a third sub-pixel electrode 210G, respectively. In an embodiment, the first organic light-emitting diode OLED1, the second organic light-emitting diode OLED2, and the third organic light-emitting diode OLED3 may commonly include the emission layer 220 and the opposite electrode 230.

The first sub-pixel electrode 210R, the second sub-pixel electrode 210B, and the third sub-pixel electrode 210G may be disposed on the planarization layer 118. Each of the first sub-pixel electrode 210R, the second sub-pixel electrode 210B, and the third sub-pixel electrode 210G may be connected to the thin-film transistor TFT. Each of the first sub-pixel electrode 210R, the second sub-pixel electrode 210B, and the third sub-pixel electrode 210G may be a (semi) light-transmissive electrode or a reflective electrode. In some embodiments, the first sub-pixel electrode 210R, the second sub-pixel electrode 210B, and the third sub-pixel electrode 210G may include a reflective layer including at least one of Ag, Mg, Al, Pt, Pd, Au, Ni, Nd, Jr, Cr, and a compound thereof, and a transparent or semitransparent electrode layer formed on the reflective layer. The transparent or semitransparent electrode layer may include at least one selected from the group including an indium tin oxide (ITO), an indium zinc oxide (IZO), ZnO, an indium oxide (In₂O₃), an indium gallium oxide (IGO), and an aluminum zinc oxide (AZO). In some embodiments, the first sub-pixel electrode 210R, the second sub-pixel electrode 210B, and the third sub-pixel electrode 210G may be provided as ITO/Ag/ITO. However, embodiments are not limited thereto.

A bank layer 119 may be disposed on the planarization layer 118. The bank layer 119 may include openings exposing central portions of the first sub-pixel electrode 210R, the second sub-pixel electrode 210B, and the third sub-pixel electrode 210G, respectively. The openings may define emission areas of the first organic light-emitting diode OLED1, the second organic light-emitting diode OLED2, and the third organic light-emitting diode OLED3, respectively, for example, a first emission area EA1, a second emission area EA2, and a third emission area EA3.

The bank layer 119 may cover edges of the first sub-pixel electrode 210R, the second sub-pixel electrode 210B, and the third sub-pixel electrode 210G. The bank layer 119 may prevent an arc or the like from occurring at the edges of the first sub-pixel electrode 210R, the second sub-pixel electrode 210B, and the third sub-pixel electrode 210G by increasing a distance between the edges of the first sub-pixel electrode 210R, the second sub-pixel electrode 210B, and the third sub-pixel electrode 210G and the opposite electrode 230 over the first sub-pixel electrode 210R, the second sub-pixel electrode 210B, and the third sub-pixel electrode 210G. The bank layer 119 may be one or more organic insulating materials selected from the group consisting of polyimide, polyamide, acrylic resin, benzocyclobutene, and phenolic resin, and may be formed by a method such as spin coating. However, embodiments are not limited thereto.

The emission layer 220 of the first organic light-emitting diode OLED1, the second organic light-emitting diode OLED2, and the third organic light-emitting diode OLED3 may include an organic material including a fluorescent or phosphorescent material emitting red light, green light, blue light, or white light. The emission layer 220 may be a low molecular weight organic material or a polymer organic material, and a functional layer such as a hole transport layer (HTL), a hole injection layer (HIL), an electron transport layer (ETL), and an electron injection layer (EIL) may be selectively disposed under and over the emission layer 220. FIGS. 4A and 4B illustrate that the emission layer 220 is integral over the first sub-pixel electrode 210R, the second sub-pixel electrode 210B, and the third sub-pixel electrode 210G, but embodiments are not limited thereto. The emission layer 220 may have various modifications, such as being arranged to correspond to each of the first sub-pixel electrode 210R, the second sub-pixel electrode 210B, and the third sub-pixel electrode 210G.

The emission layer 220 may have a stack structure including at least two emitting units emitting light of different colors. In an embodiment, the emission layer 220 may include two or more emitting units sequentially stacked each other between the sub-pixel electrode and the opposite electrode 230, and a charge generation layer disposed between two emitting units. In case that the emission layer 220 includes the two or more emitting units and the charge generation layer as described above, each of the first organic light-emitting diode OLED1, the second organic light-emitting diode OLED2, and the third organic light-emitting diode OLED3 may be a tandem light-emitting element.

In an embodiment, each of the first organic light-emitting diode OLED1, the second organic light-emitting diode OLED2, and the third organic light-emitting diode OLED3 may include a first emitting unit including a first emission layer and a second emitting unit including a second emission layer. For example, the first emission layer may be a blue emission layer, and the second emission layer may be a green emission layer. For example, the first emission layer may emit light of a first wavelength band, for example, light of a wavelength of in a range of about 450 nm to about 495 nm, and the second emission layer may emit light of a second wavelength band, for example, light of a wavelength of in a range of about 495 nm to about 570 nm.

The opposite electrode 230 may be disposed on the emission layer 220 to correspond to the first sub-pixel electrode 210R, the second sub-pixel electrode 210B, and the third sub-pixel electrode 210G (in the z direction). The opposite electrode 230 may be integral over the organic light-emitting diodes. In some embodiments, the opposite electrode 230 may be a transparent or semitransparent electrode, and may include a metal thin film having a small work function, the metal thin film including, e.g., Li, Ca, LiF/Ca, LiF/Al, Al, Ag, Mg, and a compound thereof. A transparent conductive oxide (TCO) film, such as ITO, IZO, ZnO, or In₂O₃, may be further disposed on the metal thin film. However, embodiments are not limited thereto.

In an embodiment, first light may be generated in the first emission area EA1 of the first organic light-emitting diode OLED1 and emitted to an outside. The first emission area EA1 may be defined by an opening of the bank layer 119. Second light may be generated in the second emission area EA2 of the second organic light-emitting diode OLED2 and emitted to the outside. The second emission area EA2 may be defined by an opening of the bank layer 119. Third light may be generated in the third emission area EA3 of the third organic light-emitting diode OLED3 and emitted to the outside. The third emission area EA3 may be defined by an opening of the bank layer 119.

The first emission area EA1, the second emission area EA2, and the third emission area EA3 may be apart from each other. An area other than the first emission area EA1, the second emission area EA2, and the third emission area EA3 in the display area DA may be a non-emission area. The first emission area EA1, the second emission area EA2, and the third emission area EA3 may be divided by the non-emission area. In a plan view, the first emission area EA1, the second emission area EA2, and the third emission area EA3 may be arranged in various arrangements, such as a stripe arrangement and a PenTile® arrangement. In a plan view, the first emission area EA1, the second emission area EA2, and the third emission area EA3 may each have any one of polygonal, circular, and elliptical shapes.

A spacer (not shown) for preventing mask scratches may be further provided on the bank layer 119. The spacer may be integral with the bank layer 119. For example, the spacer and the bank layer 119 may be simultaneously formed in a same process by using a halftone mask process.

The encapsulation layer 300 may be disposed on a display element (e.g., first organic light-emitting diode OLED1, second organic light-emitting diode OLED2, and third organic light-emitting diode OLED3), and may cover the display element. The first organic light-emitting diode OLED1, the second organic light-emitting diode OLED2, and the third organic light-emitting diode OLED3 may be readily damaged by moisture or oxygen from an outside, and thus, may be protected by being covered with the encapsulation layer 300. The encapsulation layer 300 may cover the display area DA and extend to an outside of the display area DA (in the x direction and/or y direction). The encapsulation layer 300 may include at least one organic encapsulation layer and at least one inorganic encapsulation layer. For example, the encapsulation layer 300 may include a first inorganic encapsulation layer 310, an organic encapsulation layer 320, and a second inorganic encapsulation layer 330.

The first inorganic encapsulation layer 310 may extend along a structure thereunder, and thus, may have an upper surface which may not be flat. The organic encapsulation layer 320 may cover the first inorganic encapsulation layer 310, and unlike the first inorganic encapsulation layer 310, may have an upper surface which may be substantially flat.

The first inorganic encapsulation layer 310 and the second inorganic encapsulation layer 330 may include one or more inorganic materials of Al₂O₃, TiO₂, Ta₂O₅, HfO₂, ZnOₓ, SiOₓ, SiNₓ, and SiON. The organic encapsulation layer 320 may include a polymer-based material. The polymer-based material may include acrylic resin, epoxy-based resin, polyimide, polyethylene, the like, or a blend thereof. In an embodiment, the organic encapsulation layer 320 may include acrylate. However, embodiments are not limited thereto.

Even in case that cracks occur in the encapsulation layer 300 via the multilayer structure described above, the encapsulation layer 300 may prevent such cracks from being connected between the first inorganic encapsulation layer 310 and the organic encapsulation layer 320 or between the organic encapsulation layer 320 and the second inorganic encapsulation layer 330. Accordingly, a formation of a path through which moisture or oxygen from an outside penetrates into the display area DA may be prevented or minimized. Although not shown, as necessary, other layers, such as a capping layer or the like, may be disposed between the first inorganic encapsulation layer 310 and the opposite electrode 230.

The color panel 20 may include the upper substrate 400, a color filter layer 500, a refractive layer RL, a first capping layer (capping layer) CL1, a second capping layer CL2, and a functional layer 700. The upper substrate 400 may be disposed over the lower substrate 100 so that a light-emitting element is disposed therebetween. The upper substrate 400 may be disposed over the first organic light-emitting diode OLED1, the second organic light-emitting diode OLED2, and the third organic light-emitting diode OLED3.

The upper substrate 400 may include a color area CA overlapping the light-emitting element. In an embodiment, the color area CA may include a first color area CA1, a second color area CA2, a third color area CA3, and a first dummy area DA1. In a plan view, the first color area CA1 may overlap the first organic light-emitting diode OLED1 and/or the first emission area EA1. In a plan view, the second color area CA2 may overlap the second organic light-emitting diode OLED2 and/or the second emission area EA2. In a plan view, the third color area CA3 may overlap the third organic light-emitting diode OLED3 and/or the third emission area EA3. In a plan view, the first dummy area DA1 may be arranged between two third color areas CA3 adjacent to each other (in the x direction).

For example, the upper substrate 400 may include at least one of glass, a metal, and polymer resin. In case that the upper substrate 400 is flexible or bendable, the upper substrate 400 may include polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate. In an embodiment, the upper substrate 400 may have a multilayer structure including two layers each including polymer resin, and a barrier layer disposed between the two layers and including an inorganic material, such as SiOₓ, SiNₓ, or SiON. However, embodiments are not limited thereto.

The color filter layer 500 may be disposed on the lower surface of the upper substrate 400 in a direction from the upper substrate 400 to the lower substrate 100 (for example, the z direction). The color filter layer 500 may include a first color filter 510, a second color filter 520, and a third color filter 530. The first color filter 510 may be disposed over the first color area CAL The second color filter 520 may be disposed over the second color area CA2. The third color filter 530 may be disposed over the third color area CA3. The first color filter 510, the second color filter 520, and the third color filter 530 may be stacked each other and disposed over the first dummy area DA1.

The first color filter 510, the second color filter 520, and the third color filter 530 may include a photosensitive resin material. Each of the first color filter 510, the second color filter 520, and the third color filter 530 may include a dye representing a unique color. The first color filter 510 may pass only light of a wavelength of in a range of about 630 nm to about 780 nm, the second color filter 520 may pass only light of a wavelength of in a range of about 450 nm to about 495 nm, and the third color filter 530 may pass only light of a wavelength of in a range of about 495 nm to about 570 nm.

The color filter layer 500 may reduce external light reflection of the display apparatus 1. For example, in case that external light reaches the first color filter 510, only light of a preset wavelength as described above may pass through the first color filter 510, and light of other wavelengths may be absorbed by the first color filter 510. Therefore, only the light of the preset wavelength among the external light incident on the display apparatus 1 may pass through the first color filter 510, and a portion thereof may be reflected from the opposite electrode 230 and/or the first sub-pixel electrode 210R thereunder and may be emitted to the outside again. Because a portion of the external light incident on the first sub-pixel PX1 is reflected to the outside, the first color filter 510 may reduce the reflection of the external light. This description may also be applied to the second color filter 520 and the third color filter 530.

The first color filter 510, the second color filter 520, and the third color filter 530 may overlap each other. The first color filter 510, the second color filter 520, and the third color filter 530 may overlap each other between non-emission areas and/or neighboring color areas CA. For example, the first color filter 510, the second color filter 520, and the third color filter 530 may overlap each other between the first color area CA1 and the second color area CA2. A portion of the third color filter 530 may be arranged between the first color area CA1 and the second color area CA2, and a portion of the first color filter 510 may extend from the first color area CA1 to an adjacent color area and overlap the second color filter 520 and the third color filter 530. The second color filter 520 may extend from the second color area CA2 to an adjacent color area and overlap the first color filter 510 and the third color filter 530.

The first color filter 510, the second color filter 520, and the third color filter 530 may overlap each other between the second color area CA2 and the third color area CA3. A portion of the first color filter 510 may be arranged between the second color area CA2 and the third color area CA3. The second color filter 520 may extend from the second color area CA2 to an adjacent color area and overlap the first color filter 510 and the third color filter 530. The third color filter 530 may extend from the third color area CA3 to an adjacent color area and overlap the first color filter 510 and the second color filter 520.

The first color filter 510, the second color filter 520, and the third color filter 530 may overlap between the third color area CA3 and the first color area CAL A portion of the second color filter 520 may be arranged between the third color area CA3 and the first color area CA1, and the third color filter 530 may extend from the third color area CA3 to an adjacent color area and overlap the first color filter 510 and the second color filter 520. The first color filter 510 may extend from the first color area CA1 to an adjacent color area and overlap the second color filter 520 and the third color filter 530.

Also, the first color filter 510, the second color filter 520, and the third color filter 530 may overlap each other over the first dummy area DA1. The first color filter 510 and the second color filter 520 may be disposed over and in correspondence with the first dummy area DA1, and the third color filter 530 may extend from the third color area CA3 to the first dummy area DA1 and overlap the first color filter 510 and the second color filter 520. The first color filter 510, the second color filter 520, and the third color filter 530 may overlap each other to form a light blocking portion. Therefore, the color filter layer 500 may prevent or reduce color mixing without a separate light blocking member.

In an embodiment, the second color filter 520 may be stacked first on the upper substrate 400 because the second color filter 520 may partially absorb external light incident from the outside of the upper substrate 400 to reduce a reflectance of the display apparatus 1, and light reflected by the second color filter 520 may be hardly recognized by a user.

The refractive layer RL may be arranged in the color area CA (in the z direction). The refractive layer RL may be arranged in each of the first color area CA1, the second color area CA2, and the third color area CA3 (in the z direction). The refractive layer RL may include an organic material. In an embodiment, a refractive index of the refractive layer RL may be less than a refractive index of the first capping layer CL1. In an embodiment, a refractive index of the refractive layer RL may be less than a refractive index of the color filter layer 500. Therefore, the refractive layer RL may concentrate light.

The second capping layer CL2 may be disposed on the refractive layer RL and the color filter layer 500. In an embodiment, the second capping layer CL2 may be disposed between the color filter layer 500 and the functional layer 700. The second capping layer CL2 may protect the refractive layer RL and the color filter layer 500. The second capping layer CL2 may prevent or reduce impurities, such as moisture and/or air, from penetrating from an outside to damage or contaminate the refractive layer RL and/or the color filter layer 500. The second capping layer CL2 may include an inorganic material.

The functional layer 700 may be disposed over the second capping layer CL2. In an embodiment, the functional layer 700 may include at least one of a color conversion material and a scatterer. In an embodiment, the color conversion material may be a quantum dot. In an embodiment, the functional layer 700 may include at least one of a first color conversion layer 710, a first transmission layer 720, a second transmission layer 730, and a material layer 740.

The first color conversion layer 710 may be arranged in the first sub-pixel PX1 (in the z direction). The first color conversion layer 710 may be patterned on the second capping layer CL2, and may overlap the first color area CAL The first color conversion layer 710 may overlap the first emission area EA1. The first sub-pixel PX1 may include the first organic light-emitting diode OLED1 and the first color conversion layer 710.

The first color conversion layer 710 may convert light of the first wavelength band generated from the emission layer 220 on the first sub-pixel electrode 210R into light of a third wavelength band. For example, in case that light of a wavelength of in a range of about 450 nm to about 495 nm is generated from the emission layer 220 on the first sub-pixel electrode 210R, the first color conversion layer 710 may convert the light into light of a wavelength of in a range of about 630 nm to about 780 nm. Therefore, in the first sub-pixel PX1, the light of the wavelength of in a range of about 630 nm to about 780 nm may be emitted to the outside through the upper substrate 400. In an embodiment, the first color conversion layer 710 may include a first quantum dot QD1, a first scatterer SC1, and a first base resin BR1. The first quantum dot QD1 and the first scatterer SC1 may be dispersed in the first base resin BR1.

The material layer 740 may be arranged between two third sub-pixels PX3 (in the x direction). The material layer 740 may be patterned on the second capping layer CL2, and may overlap the first dummy area DA1. Because the material layer area ML may be a non-pixel area in which an organic light-emitting diode is not arranged, the material layer 740 may not overlap an emission area. However, the material layer area ML may include a structure in which a portion of the first color filter 510, a portion of the second color filter 520, and a portion of the third color filter 530, which extend toward the material layer area ML, are stacked each other, and thus, the material layer 740 may overlap a portion of each of the first color filter 510, the second color filter 520, and the third color filter 530.

The material layer 740 and the first color conversion layer 710 may include a same material. In detail, the material layer 740 and the first color conversion layer 710 of the first sub-pixel PX1 may include the same material and may be simultaneously patterned via a same photolithography process. Accordingly, the material layer 740 may also convert incident light into light of the third wavelength band. In an embodiment, the material layer 740 may include a fourth quantum dot QD4, a fourth scatterer SC4, and a fourth base resin BR4. The fourth quantum dot QD4 and the fourth scatterer SC4 may be dispersed in the fourth base resin BR4.

However, because the material layer area ML may correspond to a non-pixel area (for example, a dummy sub-pixel area) in which an organic light-emitting diode is not arranged, the emission layer 220 may not be disposed under the material layer 740. Accordingly, light incident on the material layer 740 may be light emitted from the first organic light-emitting diode OLED1 of the adjacent first sub-pixel PX1, the second organic light-emitting diode OLED2 of the adjacent second sub-pixel PX2, and the third organic light-emitting diode OLED3 of the adjacent third sub-pixel PX3. Light emitted from the first organic light-emitting diode OLED1, the second organic light-emitting diode OLED2, and the third organic light-emitting diode OLED3 respectively in the first sub-pixel PX1, the second sub-pixel PX2, and the third sub-pixel PX3 may pass through the upper substrate 400 through the functional layer 700 in a vertical direction (for example, the z direction). In contrast, because light incident on the material layer 740 corresponding to the material layer area ML is not incident on the material layer 740 in the vertical direction, but in an oblique direction, a distance that light passes through the material layer 740 may be relatively long. Furthermore, a structure in which the first color filter 510, the second color filter 520, and the third color filter 530 are stacked each other over the material layer 740 may be arranged, and thus, the material layer 740 may prevent color mixing between sub-pixels arranged adjacent to each other.

Also, the material layer 740 and the first color conversion layer 710 may be formed via a same photolithography process and, may have a same thickness. A column spacer CS may be disposed over the material layer 740 in the non-pixel area, and a height of the column spacer CS may increase by patterning, in the non-pixel area, the material layer 740 having a same height as the first color conversion layer 710. For example, the material layer 740 may compensate for a step difference (or height or thickness difference) between column spacers CS.

A first capping layer CL1 may be disposed on the second capping layer CL2, the first color conversion layer 710, and the material layer 740. The first capping layer CL1 may be disposed between the first color conversion layer 710 and the first transmission layer 720 and between the second transmission layer 730 and the material layer 740. In detail, a first portion of the first capping layer CL1 may be disposed on lower surfaces of the first color conversion layer 710 and the material layer 740, a second portion of the first capping layer CL1 may be disposed on an upper surface of the first transmission layer 720, and a third portion of the first capping layer CL1 may be disposed on an upper surface of the second transmission layer 730. Accordingly, the first capping layer CL1 may protect the functional layer 700, for example, the first color conversion layer 710 and the material layer 740. The first capping layer CL1 may prevent impurities, such as moisture and/or air, from penetrating from an outside to damage or contaminate the first color conversion layer 710 and the material layer 740. The first capping layer CL1 may include a light-transmissive inorganic material.

Also, as the first capping layer CL1 is disposed between the first color conversion layer 710 and the first transmission layer 720 and between the second transmission layer 730 and the material layer 740, the first capping layer CL1 may differ from a base resin of the functional layer 700 in a refractive index, and thus, interfacial reflection may occur. Accordingly, in case that light incident on the functional layer 700 from each sub-pixel travels toward an adjacent sub-pixel, the light passing through the functional layer 700 may be reflected from the first capping layer CL1 disposed between the first color conversion layer 710 and the first transmission layer 720 and between the second transmission layer 730 and the material layer 740, and thus, the color emitted from each sub-pixel may be clearly realized and light extraction efficiency may increase.

The first transmission layer 720 may be arranged in the second sub-pixel PX2 (in the z direction). The first transmission layer 720 may be patterned on the first capping layer CL1, and may overlap the second color area CA2. The first transmission layer 720 may overlap the second emission area EA2. The second sub-pixel PX2 may include the second organic light-emitting diode OLED2 and the first transmission layer 720.

The first transmission layer 720 may emit, to an outside, light generated from the emission layer 220 on the second sub-pixel electrode 210B without wavelength conversion. For example, in case that light of a wavelength of in a range of about 450 nm to about 495 nm is generated from the emission layer 220 on the second sub-pixel electrode 210B, the first transmission layer 720 may emit the light to the outside without wavelength conversion. Even in case that the emission layer 220 emits light of two or more different colors, the first transmission layer 720 may intactly emit light of different wavelength bands without wavelength conversion. In an embodiment, the first transmission layer 720 may include a second scatterer SC2 and a second base resin BR2. The second scatterer SC2 may be dispersed in the second base resin BR2. In an embodiment, the first transmission layer 720 may not include a quantum dot.

The second transmission layer 730 may be arranged in the third sub-pixel PX3 (in the z direction). The second transmission layer 730 may be patterned on the first capping layer CL1 and may overlap the third color area CA3. The second transmission layer 730 may overlap the third emission area EA3. The third sub-pixel PX3 may include the third organic light-emitting diode OLED3 and the second transmission layer 730.

The second transmission layer 730 may emit, to an outside, light generated from the emission layer 220 on the third sub-pixel electrode 210G without wavelength conversion. For example, in case that light of a wavelength of in a range of about 450 nm to about 495 nm is generated from the emission layer 220 on the third sub-pixel electrode 210G, the second transmission layer 730 may emit the light to the outside without wavelength conversion. Even in case that the emission layer 220 emits light of two or more different colors, the second transmission layer 730 may intactly emit light of different wavelength bands without wavelength conversion. In an embodiment, the second transmission layer 730 may include a third scatterer SC3 and a third base resin BR3. The third scatterer SC3 may be dispersed in the third base resin BR3. In an embodiment, the second transmission layer 730 may not include a quantum dot.

For example, the first transmission layer 720 and the second transmission layer 730 may include a same material. For example, the second scatterer SC2 and the third scatterer SC3 may be a same scatterer, and the second base resin BR2 and the third base resin BR3 may be a same base resin. Accordingly, the first transmission layer 720 and the second transmission layer 730 may be simultaneously formed in a same process.

Also, the first transmission layer 720 and the second transmission layer 730 may extend toward the non-pixel area with respect to the second color area CA2 and the third color area CA3, respectively. Accordingly, the first transmission layer 720 of the second sub-pixel PX2 and the second transmission layer 730 of the third sub-pixel PX3 may extend, and end portions thereof may overlap end portions of the first color conversion layer 710 of the first sub-pixel PX1 and the material layer 740 of the material layer area ML, respectively. In the non-pixel area, a structure in which the first color filter 510, the second color filter 520, and the third color filter 530 also extend and are stacked each other may be arranged. Accordingly, at least one end portion of the first transmission layer 720 or the second transmission layer 730 may overlap a portion of the first color conversion layer 710, a portion of the first color filter 510, a portion of the second color filter 520, and a portion of the third color filter 530, in the non-pixel area. Therefore, in the related art, a partition wall disposed between functional layers may prevent color mixing between sub-pixels, but in the display apparatus 1 according to an embodiment, the first and second transmission layers 720 and 730 extending toward the non-pixel area may prevent color mixing between sub-pixels. This is because the second scatterer SC2 and the third scatterer SC3 respectively included in the first transmission layer 720 and the second transmission layer 730 may reflect or scatter light incident from the functional layer 700 of each sub-pixel in a lateral direction. Furthermore, the non-pixel area in which the first transmission layer 720 and the second transmission layer 730 extend may include a stack of the first color filter 510, the second color filter 520, and the third color filter 530, and a structure of the stack of the first to third color filters 510, 520, 530 may block or absorb light incident from an organic light-emitting diode included in an adjacent sub-pixel, thereby further effectively preventing color mixing.

At least one of the first quantum dot QD1 and the fourth quantum dot QD4 may include a semiconductor material, such as cadmium sulfide (CdS), cadmium telluride (CdTe), zinc sulfide (ZnS), or indium phosphide (InP). The quantum dot may have a size of several nanometers, and a wavelength of light after conversion may vary according to the size of the quantum dot.

In an embodiment, a core of the quantum dot may be selected from a Group II-VI compound, a Group III-V compound, a Group IV-VI compound, a Group IV element, a Group IV compound, and a combination thereof.

The Group II-VI compound may be selected from the group consisting of a binary compound, such as CdSe, CdTe, ZnS, ZnSe, ZnTe, ZnO, HgS, HgSe, HgTe, MgSe, MgS, and a mixture thereof; a ternary compound, such as AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a quaternary compound, such as HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof. However, embodiments are not limited thereto.

The Group III-V compound may be selected from the group consisting of a binary compound, such as GaN, GaP, GaAs, GaSb, AN, AlP, AlAs, AlSb, InN, InP, InAs, InSb, and a mixture thereof; a ternary compound, such as GaNP, GaNAs, GaNSb, GaPAs, GaPSb, AlNP, AlNAs, AlNSb, AlPAs, AlPSb, InGaP, InNP, InNAs, InNSb, InPAs, InPSb, the like, and a mixture thereof; and a quaternary compound, such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. However, embodiments are not limited thereto.

The Group IV-VI compound may be selected from the group consisting of a binary compound, such as SnS, SnSe, SnTe, PbS, PbSe, PbTe, and a mixture thereof; a ternary compound, such as SnSeS, SnSeTe, SnSTe, PbSeS, PbSeTe, PbSTe, SnPbS, SnPbSe, SnPbTe, and a mixture thereof; and a quaternary compound, such as SnPbSSe, SnPbSeTe, SnPbSTe, and a mixture thereof. The Group IV element may be selected from the group consisting of Si, Ge, and a mixture thereof. The Group IV compound may be a binary compound selected from the group consisting of SiC, SiGe, and a mixture thereof. However, embodiments are not limited thereto.

For example, the binary compound, the ternary compound, or the quaternary compound may be present in a particle at a uniform concentration, or the binary compound, the ternary compound, and the quaternary compound may have partially different concentration distributions and be present in a same particle. Also, the quantum dot may have a core/shell structure in which one quantum dot surrounds another quantum dot. The interface between the core and the shell may have a concentration gradient in which the concentration of an element presented in the shell decreases toward the center of the quantum dot.

In some embodiments, the quantum dot may have core-shell structure including a core including a nanocrystal described above and a shell surrounding the core. The shell of the quantum dot may act as a protective layer to prevent chemical degeneration of the core to maintain semiconductor characteristics and/or as a charging layer to impart electrophoretic characteristics to the quantum dot. The shell may be a single layer or a multi-layer. The interface between the core and the shell may have a concentration gradient in which the concentration of an element presented in the shell decreases toward the center of the quantum dot. Examples of the material forming the shell of the quantum dot may include an oxide of metal or non-metal, a semiconductor compound, or a combination thereof. However, embodiments are not limited thereto.

For example, the oxide of metal or non-metal may include a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, the like, or a mixture thereof, or a ternary compound, such as MgAl₂O₄, CoFe₂O₄, NiFe₂O₄, CoMn₂O₄, the like, or a mixture thereof, but embodiments are not limited thereto.

The semiconductor compound may include at least one of CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, and AlSb, but embodiments are not limited thereto.

A full width at half maximum (FWHM) of an emission wavelength spectrum of the quantum dot may be in a range of about 45 nm or less, for example, in a range of about 40 nm or less, for example, in a range of about 30 nm or less, and within these ranges, color purity or color reproducibility may be increased. Light emitted through the quantum dot is emitted in all directions, and thus, the wide viewing angle may be improved.

Also, a shape of the quantum dot is not particularly limited to a shape generally used in the related art, but in more detail, the quantum dot may be at least one of a spherical nanoparticle, a pyramidal nanoparticle, a multi-arm nanoparticle, a cubic nanoparticle, a nanotube, a nanowire, a nanofiber, and a nanoplate particle

The quantum dot may adjust a color of light emitted according to a particle size, and accordingly, the quantum dot may have various emission colors, such as blue, red, and green.

The first scatterer SC1, the second scatterer SC2, the third scatterer SC3, and the fourth scatterer SC4 may scatter light to allow more light to be emitted. The first scatterer SC1, the second scatterer SC2, the third scatterer SC3, and the fourth scatterer SC4 may increase light extraction efficiency. At least one of the first scatterer SC1, the second scatterer SC2, the third scatterer SC3, and the fourth scatterer SC4 may include any material among a metal or a metal oxide to evenly scatter light. For example, at least one of the first scatterer SC1, the second scatterer SC2, the third scatterer SC3, and the fourth scatterer SC4 may be at least one of TiO₂, ZrO₂, Al₂O₃, In₂O₃, ZnO, SnO₂, Sb₂O₃, and ITO. Also, at least one of the first scatterer SC1, the second scatterer SC2, the third scatterer SC3, and the fourth scatterer SC4 may have a refractive index of in a range of about 1.5 or more. Therefore, the light extraction efficiency of the functional layer 700 may increase. In some embodiments, at least one of the first scatterer SC1, the second scatterer SC2, the third scatterer SC3, and the fourth scatterer SC4 may be omitted.

Each of the first base resin BR1, the second base resin BR2, and the third base resin BR3 may be a light-transmissive material. For example, at least one of the first base resin BR1, the second base resin BR2, and the third base resin BR3 may include polymer resin, such as acryl, BCB, or HMDSO.

The display apparatus 1 as described above may include the first sub-pixel PX1 in which light of the third wavelength band, for example, light of a wavelength of in a range of about 630 nm to about 780 nm, may be emitted to the outside, the second sub-pixel PX2 in which light of the first wavelength band, for example, light of a wavelength of in a range of about 450 nm to about 495 nm, may be emitted to the outside, and the third sub-pixel PX3 in which light of the second wavelength band, for example, light of a wavelength of in a range of about 495 nm to about 570 nm, may be emitted to the outside. For example, the display apparatus 1 may display a full-color image.

Also, in the display apparatus 1 as described above, only the first color conversion layer 710 and the material layer 740 in the functional layer 700 may correspond to color conversion layers including quantum dots, and the first color conversion layer 710 and the material layer 740 may include a same material, and thus, may be simultaneously formed via a same process. In the related art, as an emission layer may emit a single color, a functional layer necessarily may include a first color conversion layer and a second color conversion layer, which include different materials, because the functional layer has to covert incident light into light of at least two colors. To this end, a partition wall may be formed on an upper substrate side, an opening may be arranged in the partition wall, and the functional layer may be formed by filling corresponding openings with the first color conversion layer, the second color conversion layer, and a transmission layer by an inkjet coating method. However, the inkjet process may have a low process margin when applied to high-resolution products, and may require more time than the photolithography process. In contrast, in the display apparatus 1 according to an embodiment, because the first color conversion layer 710 and the material layer 740, which include quantum dots, in the functional layer 700 include a single material, the first color conversion layer 710 and the material layer 740 may be patterned directly on the second capping layer CL2 without a partition wall. Accordingly, as the first color conversion layer 710 and the material layer 740 are patterned by the photolithography process without performing a process of forming a partition wall and an opening and an inkjet process, the display apparatus 1 according to an embodiment may be readily designed to have a high resolution, and may have reduced manufacturing costs.

The filling layer 30 may be disposed between the light-emitting panel 10 and the color panel 20. In an embodiment, the filling layer 30 may be disposed between the encapsulation layer 300 and the functional layer 700. The filling layer 30 may act as a buffer against external pressure or the like. The filling layer 30 may include a filler. In an embodiment, the filling layer 30 may include a thermosetting or photocurable filler. The filler may include an organic material, such as methyl silicone, phenyl silicone, or polyimide. However, embodiments are not limited thereto, and the filler may include an inorganic sealant, silicone, or an organic sealant such as urethane-based resin, epoxy-based resin, or acrylic resin.

One of the light-emitting panel 10 and the color panel 20 may include the column spacer CS. In an embodiment, the color panel 20 may include the column spacer CS. In another embodiment, the light-emitting panel 10 may include the column spacer CS. Hereinafter, a case in which the color panel 20 includes the column spacer CS is mainly described in detail. The column spacer CS may be disposed over the functional layer 700 and may face the lower substrate 100 (or light-emitting panel 10). The column spacer CS may separate the encapsulation layer 300 and the functional layer 700 from each other. The column spacer CS may pass through the filling layer 30.

The column spacer CS may separate the light-emitting element and the functional layer 700 from each other at a uniform distance. Therefore, the filling layer 30 may be arranged in the display area DA while having a uniform thickness. For example, a distance between the first organic light-emitting diode OLED1 and the first color conversion layer 710 may be substantially equal to a distance between the second organic light-emitting diode OLED2 and the first transmission layer 720. Also, the distance between the second organic light-emitting diode OLED2 and the first transmission layer 720 may be substantially equal to a distance between the third organic light-emitting diode OLED3 and the second transmission layer 730. In case that the column spacer CS is omitted unlike the embodiment, the light-emitting elements and the functional layer may not maintain a uniform distance. For example, a thickness of the filling layer 30 in the first color area CA1 may be different from a thickness of the filling layer 30 in the second color area CA2. A luminance of light emitted from the first organic light-emitting diode OLED1 and passing through the filling layer 30 overlapping the first color area CA1 may be different from a luminance of light emitted from the second organic light-emitting diode OLED2 and passing through the filling layer 30 overlapping the second color area CA2. In the embodiment, the column spacer CS may be arranged to pass through the filling layer 30, and may separate the light-emitting element and the functional layer 700 from each other at a uniform distance. Also, a phenomenon in which luminance varies according to positions in the display area DA due to the filling layer 30 may be prevented or reduced.

The column spacer CS may at least partially overlap the bank layer 119 disposed thereunder. Because the column spacer CS at least partially overlaps the bank layer 119, the column spacer CS may at least partially overlap the non-emission area of each sub-pixel or the non-pixel area. Therefore, the column spacer CS may not overlap the emission area of each sub-pixel. Referring to FIGS. 3 to 4B, the column spacer CS may be arranged between two adjacent third sub-pixels PX3. For example, the column spacer CS may be disposed over the material layer 740 in the material layer area ML.

The column spacer CS may include an organic material, for example, an acrylic material. In an embodiment, the column spacer CS, the first transmission layer 720, and the second transmission layer 730 may include a same material. For example, the column spacer CS may include a scatter substantially identical or similar to the second scatterer SC2, and a base resin. The base resin and the second base resin BR2 may include a same material. For example, the scatterer of the column spacer CS may be dispersed in the base resin. The column spacer CS, the first transmission layer 720, and the second transmission layer 730 may include a same material, and thus, may be simultaneously formed via a same process. In the related art, a transmission layer and a column spacer include different materials, and thus, are necessarily formed via different processes. However, in the display apparatus 1 according to an embodiment of the disclosure, the material layer 740 including a same material as the first color conversion layer 710 may be disposed under the column spacer CS to compensate for a step difference, and because the column spacer CS including a same material as the first transmission layer 720 and the second transmission layer 730 is formed over the material layer 740, the first transmission layer 720, the second transmission layer 730, and the column spacer CS may be patterned by using one mask. Accordingly, the manufacturing cost may be reduced, and the number of processes and the manufacturing time may be shortened to increase productivity.

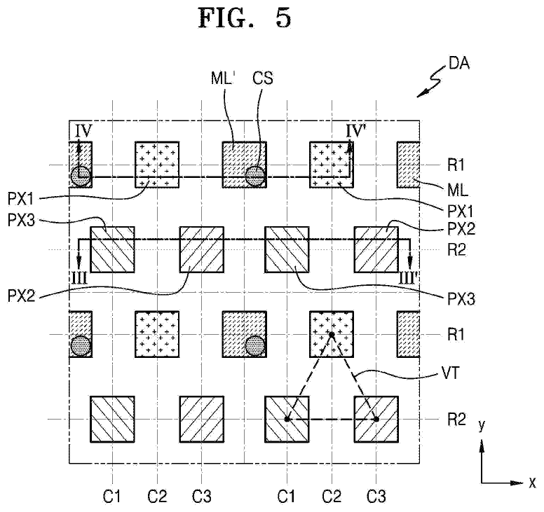

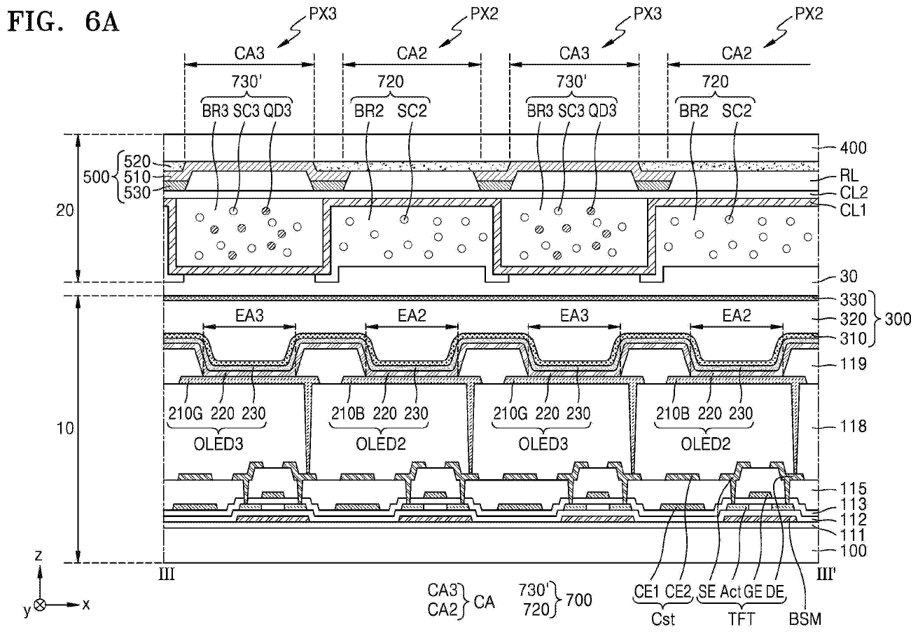

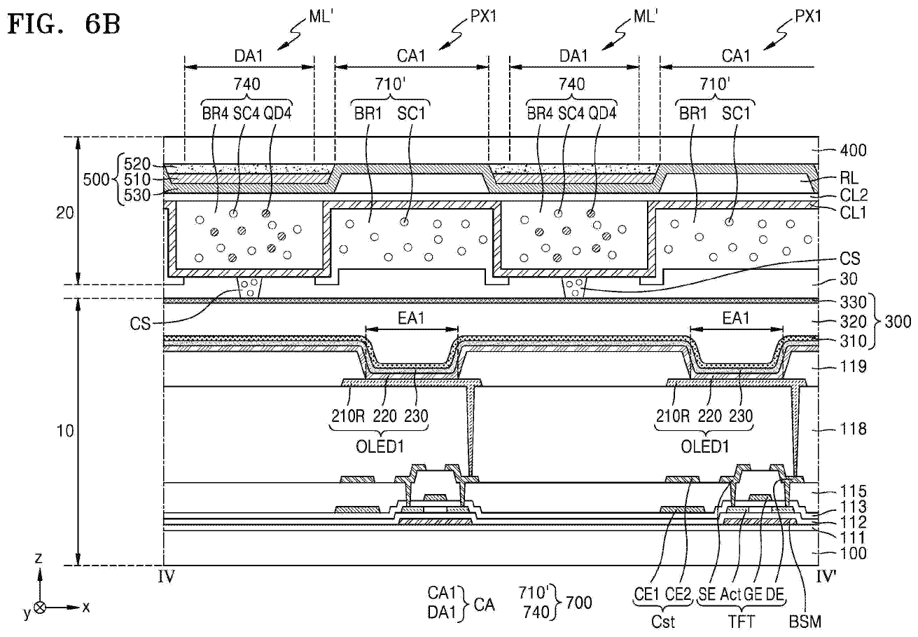

FIG. 5 is a schematic plan view of portion of a display area of a display apparatus 1 according to another embodiment, FIG. 6A is a schematic cross-sectional view of a color panel of FIG. 5 taken along line III-III′ of FIG. 5, and FIG. 6B is a schematic cross-sectional view of the color panel of FIG. 5 taken along line IV-IV′ of FIG. 5. Referring to FIGS. 5 to 6B, except for features of the functional layer 700 arranged in the first sub-pixel PX1 and the functional layer 700 arranged in the third sub-pixel PX3, other features may be substantially identical or similar to those described with reference to FIGS. 3 to 4B. Same reference numerals among components of FIGS. 5 to 6B are substituted for those previously described with reference to FIGS. 3 to 4B, and differences are mainly described in following description.

Referring to FIG. 5, the display apparatus 1 may include an array of sub-pixels arranged in the display area DA, and the array of sub-pixels may include the first sub-pixels PX1, the second sub-pixels PX2, and the third sub-pixels PX3 that are two-dimensionally arranged. The array of sub-pixels may have a two-dimensional configuration of minimal repeating units, and may have different arrangements in an x direction and a y direction.

When viewing the arrangement of the sub-pixels in the x direction, the array of the sub-pixels may have a configuration in which two rows in the x direction are repeatedly arranged. The first sub-pixels PX1 may be arranged along the first row R1 in the x direction, and the third sub-pixel PX3 and the second sub-pixel PX2 may be alternately arranged along the second row R2 in the x direction, the second row R2 being parallel to the first row R1. When viewing the arrangement of the sub-pixels in the y direction, sub-pixels emitting light of a same color may be arranged in each column in the y direction. The third sub-pixels PX3 may be arranged along the first column C1, the first sub-pixels PX1 may be arranged along the second column C2, and the second sub-pixels PX2 may be arranged along the third column C3. Also, a material layer area ML′ may be arranged between two adjacent first sub-pixels PX1 (e.g., in the x direction). For example, the first sub-pixel PX1 and the material layer area ML′ may be alternately arranged along the first row R1 in the x direction.

Referring to FIGS. 6A and 6B, the first organic light-emitting diode OLED1, the second organic light-emitting diode OLED2, and the third organic light-emitting diode OLED3 may be arranged in the first sub-pixel PX1, the second sub-pixel PX2, and the third sub-pixel PX3, respectively. The emission layer 220 of the first organic light-emitting diode OLED1, the second organic light-emitting diode OLED2, and the third organic light-emitting diode OLED3 may include an organic material including a fluorescent or phosphorescent material emitting red light, green light, blue light, or white light. Also, the emission layer 220 may have a structure including a stack of at least two light emitting parts (or light emitting units) emitting light of different colors, and each of the first organic light-emitting diode OLED1, the second organic light-emitting diode OLED2, and the third organic light-emitting diode OLED3 may be a tandem light-emitting element.

In an embodiment, each of the first organic light-emitting diode OLED1, the second organic light-emitting diode OLED2, and the third organic light-emitting diode OLED3 may include a first emitting unit including a first emission layer and a second emitting unit including a second emission layer. For example, the first emission layer may be a blue emission layer, and the second emission layer may be a red emission layer. For example, the first emission layer may emit light of a wavelength of in a range of about 450 nm to about 495 nm, and the second emission layer may emit light of the third wavelength band, for example, light of a wavelength of in a range of about 630 nm to about 780 nm.

Accordingly, in the display apparatus 1 according to another embodiment, the functional layer 700 arranged in the color panel 20 may include a first color conversion layer 730′, the first transmission layer 720, a second transmission layer 710′, and the material layer 740.

The first color conversion layer 730′ may be arranged in the third sub-pixel PX3. The first color conversion layer 730′ may be patterned on the second capping layer CL2, and may overlap the third color area CA3 and the third emission area EA3. The third sub-pixel PX3 may include the third organic light-emitting diode OLED3 and the first color conversion layer 730′.

The first color conversion layer 730′ may convert light of the first wavelength band generated from the emission layer 220 on the third sub-pixel electrode 210G into light of the second wavelength band. For example, in case that light of a wavelength of in a range of about 450 nm to about 495 nm is generated from the emission layer 220 on the third sub-pixel electrode 210G, the first color conversion layer 730′ may convert the light into light of a wavelength of in a range of about 495 nm to about 570 nm. Therefore, in the third sub-pixel PX3, the light of the wavelength of in a range of about 495 nm to about 570 nm may be emitted to the outside through the upper substrate 400. In an embodiment, the first color conversion layer 730′ may include a third quantum dot QD3, the third scatterer SC3, and the third base resin BR3. The third quantum dot QD3 and the third scatterer SC3 may be dispersed in the third base resin BR3.

For example, the material layer 740 and the first color conversion layer 730′ may include a same material. Accordingly, the material layer 740 may also convert incident light into light of the second wavelength band. For example, the material layer 740 and the first color conversion layer 730′ of the third sub-pixel PX3 may include a same material and may be simultaneously patterned via a same photolithography process.

The second transmission layer 710′ may be arranged in the first sub-pixel PX1 (in the z direction). The second transmission layer 710′ may be patterned on the first capping layer CL1 and may overlap the first color area CAL The second transmission layer 710′ may overlap the first emission area EA1. The first sub-pixel PX1 may include the first organic light-emitting diode OLED1 and the second transmission layer 710′.

Therefore, in the display apparatus 1 according to another embodiment, because the first color conversion layer 710 and the material layer 740, which include quantum dots, in the functional layer 700 may include a single material, the first color conversion layer 710 and the material layer 740 may be patterned (e.g., patterned directly) on the second capping layer CL2 without a partition wall. However, unlike the display apparatus 1 according to an embodiment, in the display apparatus 1 of FIGS. 3 to 4B, the first color conversion layer 710 is arranged in the first sub-pixel PX1, and thus, the first color conversion layer 710 may convert incident light into red light, but in the display apparatus 1 of FIGS. 5 to 6B, the first color conversion layer 730′ is arranged in the third sub-pixel PX3, and thus, the first color conversion layer 730′ may convert incident light into green light. In the display apparatuses 1 according to embodiments, the first color conversion layer 710 or 730′ may be selectively arranged in the first sub-pixel PX1 or in the third sub-pixel PX3. Accordingly, even in case that the organic light-emitting diodes emit blue light or red light, light of the third wavelength band may be emitted to the outside in the first sub-pixel PX1, light of the first wavelength band may be emitted to the outside in the second sub-pixel PX2, and light of the second wavelength band may be emitted to the outside in the third sub-pixel PX3. Therefore, the display apparatus 1 according to another embodiment may also clearly display a full-color image.

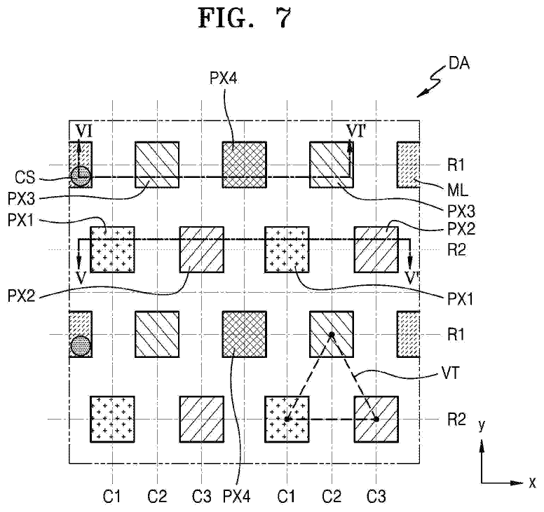

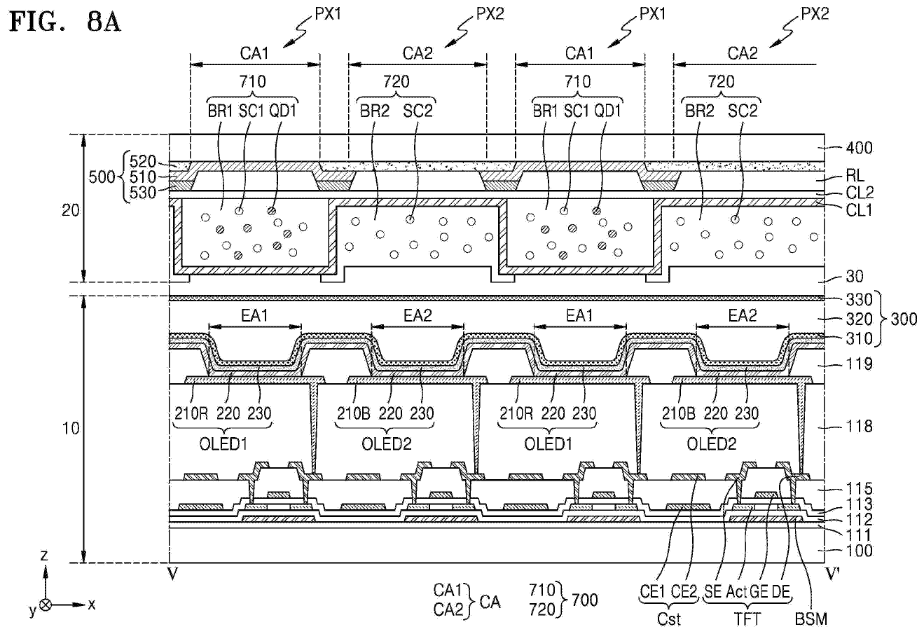

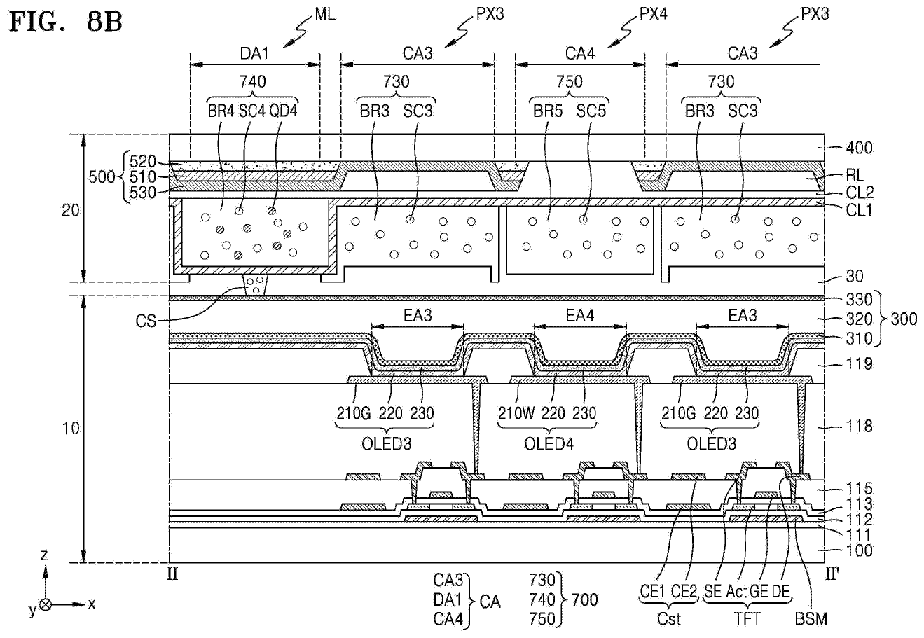

FIG. 7 is a schematic plan view of a portion of a display area of a display apparatus 1 according to another embodiment, FIG. 8A is a schematic cross-sectional view of a color panel of FIG. 7 taken along line V-V′ of FIG. 7, and FIG. 8B is a schematic cross-sectional view of the color panel of FIG. 7 taken along line VI-VI′ of FIG. 7. Referring to FIGS. 7 to 8B, except for features of a fourth sub-pixel PX4, other features may be substantially identical or similar to those described with reference to FIGS. 3 to 4B. Same reference numerals among components of FIGS. 7 to 8B are substituted for those previously described with reference to FIGS. 3 to 4B, and differences are mainly described in following description.

Referring to FIG. 7, the display apparatus 1 may include an array of sub-pixels arranged in the display area DA, and the array of sub-pixels may include the first sub-pixels PX1, the second sub-pixels PX2, the third sub-pixels PX3, and fourth sub-pixels PX4 that are two-dimensionally arranged. The array of sub-pixels may have a two-dimensional configuration of minimal repeating units, and may have different arrangements in an x direction and a y direction.

The array of the sub-pixels may have a two-dimensional configuration of minimal repeating units, and may have different arrangements in the x direction and the y direction.

When viewing the arrangement of the sub-pixels in the x direction, the array of the sub-pixels may have a configuration in which two rows in the x direction are repeatedly arranged. The third sub-pixels PX3 may be arranged along the first row R1 in the x direction, and the first sub-pixel PX1 and the second sub-pixel PX2 may be alternately arranged along the second row R2 in the x direction, the second row R2 being parallel to the first row R1. The array of the sub-pixels may have a structure in which the first row R1 and the second row R2 of the above-described structure are repeatedly arranged.

The first sub-pixels PX1 emitting a first color, the second sub-pixels PX2 emitting a second color, and the third sub-pixels PX3 emitting a third color may be arranged apart from each other with a non-pixel area therebetween. For example, the material layer area ML and/or the fourth sub-pixel PX4 may be arranged between two adjacent third sub-pixels PX3 (e.g., in the x direction).

In an embodiment, the material layer area ML and the fourth sub-pixel PX4 may be alternately arranged in a ratio of 1:1 in a repetitive manner. The material layer area ML, the third sub-pixel PX3, and the fourth sub-pixel PX4 may be alternately arranged along the first row R1 in the x direction. As another example, the material layer area ML and the fourth sub-pixel PX4 may be alternately arranged at a ratio of n:1 in a repetitive manner. The third sub-pixel PX3 and the material layer area ML may be alternately arranged along the first row R1 in the x direction, and instead of the material layer area ML, the fourth sub-pixel PX4 may be arranged at an nth-order position.

Referring to FIGS. 8A and 8B, a display apparatus 1 according to another embodiment may include the first sub-pixel PX1, the second sub-pixel PX2, the third sub-pixel PX3, the fourth sub-pixel PX4, and the material layer area ML, which are arranged in the display area DA. The first sub-pixel PX1, the second sub-pixel PX2, the third sub-pixel PX3, and the fourth sub-pixel PX4 may implement or emit different light. For example, the first sub-pixel PX1 may implement red light, the second sub-pixel PX2 may implement blue light, the third sub-pixel PX3 may implement green light, and the fourth sub-pixel PX4 may implement white light.

The first organic light-emitting diode OLED1, the second organic light-emitting diode OLED2, the third organic light-emitting diode OLED3, and a fourth organic light-emitting diode OLED4 may be arranged in the first sub-pixel PX1, the second sub-pixel PX2, the third sub-pixel PX3, and the fourth sub-pixel PX4, respectively. The first organic light-emitting diode OLED1, the second organic light-emitting diode OLED2, the third organic light-emitting diode OLED3, and the fourth organic light-emitting diode OLED4 may include the first sub-pixel electrode 210R, the second sub-pixel electrode 210B, the third sub-pixel electrode 210G, and a fourth sub-pixel electrode 210W, respectively. In an embodiment, the first organic light-emitting diode OLED1, the second organic light-emitting diode OLED2, and the third organic light-emitting diode OLED3 may commonly include the emission layer 220 and the opposite electrode 230.

The emission layer 220 of the first organic light-emitting diode OLED1, the second organic light-emitting diode OLED2, and the third organic light-emitting diode OLED3 may have a structure including a stack of at least two emitting units emitting light of different colors, and each of the first organic light-emitting diode OLED1, the second organic light-emitting diode OLED2, and the third organic light-emitting diode OLED3 may be a tandem light-emitting element.

In an embodiment, each of the first organic light-emitting diode OLED1, the second organic light-emitting diode OLED2, and the third organic light-emitting diode OLED3 may include a first emitting unit including a first emission layer, a second emitting unit including a second emission layer, and a third emitting unit including a third emission layer. The first emission layer may be a blue emission layer, the second emission layer may be a green emission layer, and the third emission layer may be a red emission layer. For example, the first emission layer may emit light of the first wavelength band, for example, light of a wavelength of in a range of about 450 nm to about 495 nm, the second emission layer may emit light of the second wavelength band, for example, light of a wavelength of in a range of about 495 nm to about 570 nm, and the third emission layer may emit light of the third wavelength band, for example, light of a wavelength of in a range of about 630 nm to about 780 nm. For example, the emission layer 220 of the fourth organic light-emitting diode OLED4 may include a structure including a stack of a blue emission layer, a green emission layer, and a red emission layer, and thus, the fourth sub-pixel PX4 may emit white light.

The upper substrate 400 may include the color area CA overlapping a light-emitting element (or an emission area). In an embodiment, the color area CA may include the first color area CA1, the second color area CA2, the third color area CA3, the first dummy area DA1, and a fourth color area CA4. In a plan view, the fourth color area CA4 may overlap the fourth organic light-emitting diode OLED4 and/or a fourth emission area EA4.

The color filter layer 500 may be disposed on the lower surface of the upper substrate 400 in a direction from the upper substrate 400 to the lower substrate 100. The color filter layer 500 may include the first color filter 510, the second color filter 520, and the third color filter 530. The first color filter 510 may be disposed over the first color area CAL The second color filter 520 may be disposed over the second color area CA2. The third color filter 530 may be disposed over the third color area CA3. The first color filter 510, the second color filter 520, and the third color filter 530 may be stacked each other and disposed over the first dummy area DA1. However, the first color filter 510, the second color filter 520, and the third color filter 530 may not be arranged in the fourth color area CA4. Accordingly, the color filter layer 500 may be not arranged in the fourth sub-pixel PX4, and thus, the white light emitted from the fourth organic light-emitting diode OLED4 may be intactly emitted to the outside through the upper substrate 400.

Also, the functional layer 700 may include the first color conversion layer 710, the first transmission layer 720, the second transmission layer 730, the material layer 740, and a third transmission layer 750.

The third transmission layer 750 may be arranged in the fourth sub-pixel PX4. The third transmission layer 750 may be patterned on the first capping layer CL1 and may overlap the fourth color area CA4. The third transmission layer 750 may overlap the fourth emission area EA4. The fourth sub-pixel PX4 may include the fourth organic light-emitting diode OLED4 and the third transmission layer 750.

The third transmission layer 750 may emit, to the outside, light generated from the emission layer 220 on the fourth sub-pixel electrode 210W without wavelength conversion. For example, in case that white light is generated from the emission layer 220 on the fourth sub-pixel electrode 210W, the third transmission layer 750 may emit the light to the outside without wavelength conversion. In an embodiment, the third transmission layer 750 may include a fifth scatterer SC5 and a fifth base resin BR5. The fifth scatterer SC5 may be dispersed in the fifth base resin BR5. In an embodiment, the third transmission layer 750 may not include a quantum dot.

For example, the third transmission layer 750, the first transmission layer 720, and the second transmission layer 730 may include a same material. For example, the fifth scatterer SC5 may be substantially identical or similar to the second scatterer SC2 and the third scatterer SC3, and the fifth base resin BR5 may be substantially identical or similar to the second base resin BR2 and the third base resin BR3.

Therefore, the first transmission layer 720, the second transmission layer 730, and the third transmission layer 750 may be simultaneously formed in a same process. Without an additional process for the third transmission layer 750, the third transmission layer 750 for emitting white light from the fourth sub-pixel PX4 may be patterned by using one mask. Accordingly, in the display apparatus 1 according to another embodiment, the fourth sub-pixel PX4 capable of emitting white light may be additionally formed without increases in manufacturing cost, the number of processes, and manufacturing time. As a result, the display apparatus 1 as described above may include the first sub-pixel PX1 in which light of the third wavelength band, for example, light of a wavelength of in a range of about 630 nm to about 780 nm, may be emitted to the outside, the second sub-pixel PX2 in which light of the first wavelength band, for example, light of a wavelength of in a range of about 450 nm to about 495 nm, may be emitted to the outside, the third sub-pixel PX3 in which light of the second wavelength band, for example, light of a wavelength of in a range of about 495 nm to about 570 nm, may be emitted to the outside, and the fourth sub-pixel PX4 in which white light as a mixture of light of various wavelength bands may be emitted to the outside. For example, the display apparatus 1 according to another embodiment may display a full-color image in which colors are clearly implemented, and may have increased light extraction efficiency.

As the organic light-emitting diode includes at least two emission layers emitting light of different colors, the first color conversion layer may be arranged in the first sub-pixel, and the first transmission layer and the second transmission layer may be arranged in the second sub-pixel and the third sub-pixel, by simplifying a process, the display apparatus 1 according to an embodiment as described above may have reduced manufacturing costs, even while visibility and light efficiency are maintained or increased.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display apparatus comprising:
first sub-pixels of a first color, second sub-pixels of a second color, and third sub-pixels of a third color which are apart from each other with a non-pixel area disposed between the first sub-pixels, the second sub-pixels, and the third sub-pixels;
organic light-emitting diodes disposed over a lower substrate to correspond to the first sub-pixels, the second sub-pixels, and the third sub-pixels, respectively, and each comprising:
a first electrode;
at least two emission layers emitting light of different colors; and
a second electrode;
a color conversion layer disposed over one of the organic light-emitting diodes corresponding to one of the first sub-pixels, and comprising quantum dots converting incident light into light of the first color;
a first color filter disposed over the color conversion layer and transmitting light of the first color;
a first transmission layer disposed over one of the organic light-emitting diodes corresponding to one of the second sub-pixels;
a second color filter disposed over the first transmission layer and transmitting light of the second color different from the first color;
a second transmission layer disposed over one of the organic light-emitting diodes corresponding to one of the third sub-pixels; and
a third color filter disposed over the second transmission layer and transmitting light of the third color different from the first color and the second color,
wherein a material of the first transmission layer is identical to a material of the second transmission layer.

2. The display apparatus of claim 1, wherein
the first transmission layer and the second transmission layer extend toward the non-pixel area, and
in the non-pixel area, an end portion of the first transmission layer and an end portion of the second transmission layer overlap an end portion of the color conversion layer in a plan view.

3. The display apparatus of claim 1, wherein a column spacer is arranged between two adjacent third sub-pixels among the third sub-pixels.

4. The display apparatus of claim 3, further comprising:
a material layer arranged between the two adjacent third sub-pixels, the material layer and the color conversion layer comprising a same material, wherein
a portion of the first color filter, a portion of the second color filter, and a portion of the third color filter extend between the two adjacent third sub-pixels and overlap each other in a plan view, and
the portion of the first color filter, the portion of the second color filter, the portion of the third color filter, and the material layer overlap the column spacer in a plan view.

5. The display apparatus of claim 3, wherein the column spacer, the first transmission layer, and the second transmission layer comprise a same material.

6. The display apparatus of claim 1, wherein
the organic light-emitting diodes emit blue light and green light, and
the quantum dots convert incident light into red light.

7. The display apparatus of claim 1, wherein
the organic light-emitting diodes emit blue light and red light, and
the quantum dots convert incident light into green light.

8. The display apparatus of claim 1, wherein the organic light-emitting diodes emit red light, green light, and blue light.

9. The display apparatus of claim 8, further comprising:
fourth sub-pixels of a fourth color; and
a third transmission layer overlapping one of the organic light-emitting diodes corresponding to one of the fourth sub-pixels in a plan view.

10. The display apparatus of claim 9, wherein a material of the third transmission layer is identical to the material of the first transmission layer and the material of the second transmission layer.

11. The display apparatus of claim 9, wherein
the fourth sub-pixels and the third sub-pixels are arranged along a same row, and
one of the fourth sub-pixels is arranged between two adjacent third sub-pixels among the third sub-pixels.

12. The display apparatus of claim 1, further comprising:
a capping layer, wherein
a first portion of the capping layer is disposed on a lower surface of the color conversion layer,
a second portion of the capping layer is disposed on an upper surface of the first transmission layer, and
a third portion of the capping layer is disposed on an upper surface of the second transmission layer.

13. The display apparatus of claim 12, wherein the capping layer comprises a light-transmissive inorganic material.

14. A display apparatus comprising:
first sub-pixels of a first color, second sub-pixels of a second color, and third sub-pixels of a third color which are apart from each other with a non-pixel area disposed between the first sub-pixels, the second sub-pixels, and the third sub-pixels;
organic light-emitting diodes disposed over a lower substrate to correspond to the first sub-pixels, the second sub-pixels, and the third sub-pixels, respectively, and each comprising a first electrode, at least two emission layers emitting light of different colors, and a second electrode;
a color conversion layer disposed over one of the organic light-emitting diodes corresponding to one of the first sub-pixels, and comprising quantum dots converting incident light into light of the first color;
a first color filter disposed over the color conversion layer and transmitting light of the first color;
a first transmission layer disposed over one of the organic light-emitting didoes corresponding to one of the second sub-pixels;
a second color filter disposed over the first transmission layer and transmitting light of the second color different from the first color;
a second transmission layer disposed over one of the organic light-emitting diodes corresponding to one of the third sub-pixels; and
a third color filter disposed over the second transmission layer and transmitting light of the third color different from the first color and the second color, wherein
the first to third color filters extend toward the non-pixel area, and
at least one end portion of the first transmission layer or the second transmission layer overlaps a portion of the color conversion layer, a portion of the first color filter, a portion of the second color filter, and a portion of the third color filter, in the non-pixel area in a plan view.

15. The display apparatus of claim 14, wherein a column spacer is arranged between two adjacent third sub-pixels among the third sub-pixels.

16. The display apparatus of claim 15, further comprising:
a first color filter layer, the first color filter layer and the first color filter comprising a same material;
a second color filter layer, the second color filter layer and the second color filter comprising a same material;
a third color filter layer, the third color filter layer and the third color filter comprising a same material; and
a material layer, the material layer and the color conversion layer comprising a same material, wherein
the first color filter layer, the second color filter layer, the third color filter layer, and the material layer are arranged between the two adjacent third sub-pixels, and
the first color filter layer, the second color filter layer, the third color filter layer, and the material layer overlap the column spacer in a plan view.

17. The display apparatus of claim 15, wherein the column spacer, the first transmission layer, and the second transmission layer comprises a same material.

18. The display apparatus of claim 14, wherein the organic light-emitting diodes emit red light, green light, and blue light.

19. The display apparatus of claim 18, further comprising:
fourth sub-pixels of a fourth color; and
a third transmission layer overlapping one of the organic light-emitting diodes corresponding to one of the fourth sub-pixels in a plan view.

20. The display apparatus of claim 19, wherein a material of the third transmission layer is identical to a material of the first transmission layer and a material of the second transmission layer.

21. The display apparatus of claim 19, wherein
the fourth sub-pixels and the third sub-pixels are arranged along a same row, and
one of the fourth sub-pixels is arranged between two adjacent third sub-pixels among the third sub-pixels.

22. The display apparatus of claim 14, further comprising:
a capping layer, wherein
a first portion of the capping layer is disposed on a lower surface of the color conversion layer,
a second portion of the capping layer is disposed on an upper surface of the first transmission layer, and
a third portion of the capping layer is disposed on an upper surface of the second transmission layer.
